(19) United States
(12) Patent Application Publication
(10) Pub. No.: US 2025/0069996 A1
(43) Pub. Date: Feb. 27, 2025

(54) SEMICONDUCTOR DEVICE AND METHOD FOR MANUFACTURING SEMICONDUCTOR DEVICE

(71) Applicant: Rohm Co., Ltd., Kyoto-shi (JP)

(72) Inventor: Hiroaki MATSUBARA, Kyoto-shi (JP)

(21) Appl. No.: 18/943,499

(22) Filed: Nov. 11, 2024

Related U.S. Application Data
(63) Continuation of application No. PCT/JP2023/016432, filed on Apr. 26, 2023.

(30) Foreign Application Priority Data
May 13, 2022 (JP) 2022-079839
Apr. 19, 2023 (JP) 2023-068389

(51) Int. Cl. H01L 23/495; H01L 21/48; H01L 25/065

(52) U.S. Cl. CPC H01L 23/49555; H01L 21/4842; H01L 23/49582; H01L 23/49575; H01L 25/0655

(57) ABSTRACT

A semiconductor device includes a semiconductor element, a sealing resin covering the semiconductor element, a terminal electrically connected to the semiconductor element and protruding from the sealing resin in a first direction orthogonal to a thickness direction, and a plating layer located on the terminal. The terminal includes an end surface at a distal end protruding from the sealing resin, a first surface facing a first side in the thickness direction, and a recess recessed from both the end surface and the first surface. The plating layer includes a recess plating section located on at least a portion of the recess.

### TECHNICAL FIELD

The present disclosure relates to a semiconductor device and a method for manufacturing a semiconductor device.

### BACKGROUND ART

Various configurations have been proposed for semiconductor devices that incorporate semiconductor elements. JP-A-2016-207714 discloses an example of a semiconductor device of the small outline package (SOP) type. The semiconductor device disclosed in JP-A-2016-207714 includes a semiconductor element, a die pad, terminals, and a sealing resin. The semiconductor element is mounted on the die pad and electrically connected to the terminals via bonding wires. The semiconductor element, the die pad, and portions of the terminals are covered with the sealing resin. Portions of the terminals exposed from the sealing resin are coated with an external plating layer made from an alloy containing Sn. This improves the solderability of the terminals to be bonded to a wiring board using solder.

### BRIEF DESCRIPTION OF THE DRAWINGS

FIG. 1 is a plan view of a semiconductor device according to a first embodiment of the present disclosure.

FIG. 2 is a plan view of the semiconductor device shown in FIG. 1, with a sealing resin shown as transparent.

FIG. 3 is a front view of the semiconductor device shown in FIG. 1.

FIG. 4 is a left-side view of the semiconductor device shown in FIG. 1.

FIG. 5 is a sectional view taken along line V-V in FIG. 2.

FIG. 6 is a sectional view taken along line VI-VI in FIG. 2.

FIG. 7 is a partial enlarged view of FIG. 5.

FIG. 8 is a partial enlarged view of FIG. 4.

FIG. 9 is a partial enlarged view of FIG. 5.

FIG. 10 is a plan view illustrating a step of a method for manufacturing the semiconductor device shown in FIG. 1.

FIG. 11 is a bottom view illustrating a step of the method for manufacturing the semiconductor device shown in FIG. 1.

FIG. 12 is a sectional view illustrating a step of the method for manufacturing the semiconductor device shown in FIG. 1.

FIG. 13 is a plan view illustrating a step of the method for manufacturing the semiconductor device shown in FIG. 1.

FIG. 14 is a plan view illustrating a step of the method for manufacturing the semiconductor device shown in FIG. 1.

FIG. 15 is a sectional view illustrating a step of the method for manufacturing the semiconductor device shown in FIG. 1.

FIG. 16 is a sectional view illustrating a step of the method for manufacturing the semiconductor device shown in FIG. 1.

FIG. 17 is a partial enlarged view of FIG. 16.

FIG. 18 is a sectional view illustrating a step of the method for manufacturing the semiconductor device shown in FIG. 1.

FIG. 19 is a sectional view illustrating a step of the method for manufacturing the semiconductor device shown in FIG. 1.

FIG. 20 is a partial enlarged view of FIG. 19.

FIG. 21 is a partial enlarged sectional view of the semiconductor device of FIG. 1 in a state mounted on a wiring board.

FIG. 22 is a partial enlarged left-side view of a semiconductor device according to a first variation of the first embodiment of the present disclosure.

FIG. 23 is a partial enlarged bottom view of the semiconductor device shown in FIG. 22.

FIG. 24 is a partial enlarged left-side view of a semiconductor device according to a second variation of the first embodiment of the present disclosure.

FIG. 25 is a partial enlarged bottom view of the semiconductor device shown in FIG. 24.

FIG. 26 is a partial enlarged left-side view of a semiconductor device according to a third variation of the first embodiment of the present disclosure.

FIG. 27 is a partial enlarged bottom view of the semiconductor device shown in FIG. 26.

FIG. 28 is a partial enlarged sectional view of a semiconductor device according to a second embodiment of the present disclosure.

FIG. 29 is a partial enlarged left-side view of the semiconductor device shown in FIG. 28.

FIG. 30 is a partial enlarged sectional view illustrating a step of a method for manufacturing the semiconductor device shown in FIG. 28.

FIG. 31 is a partial enlarged sectional view of a semiconductor device according to a third embodiment of the present disclosure.

FIG. 32 is a partial enlarged left-side view of the semiconductor device shown in FIG. 31.

FIG. 33 is a partial enlarged sectional view of a semiconductor device according to a fourth embodiment of the present disclosure.

### DETAILED DESCRIPTION OF EMBODIMENTS

The following describes preferred embodiments of the present disclosure in detail with reference to the drawings.

### First Embodiment

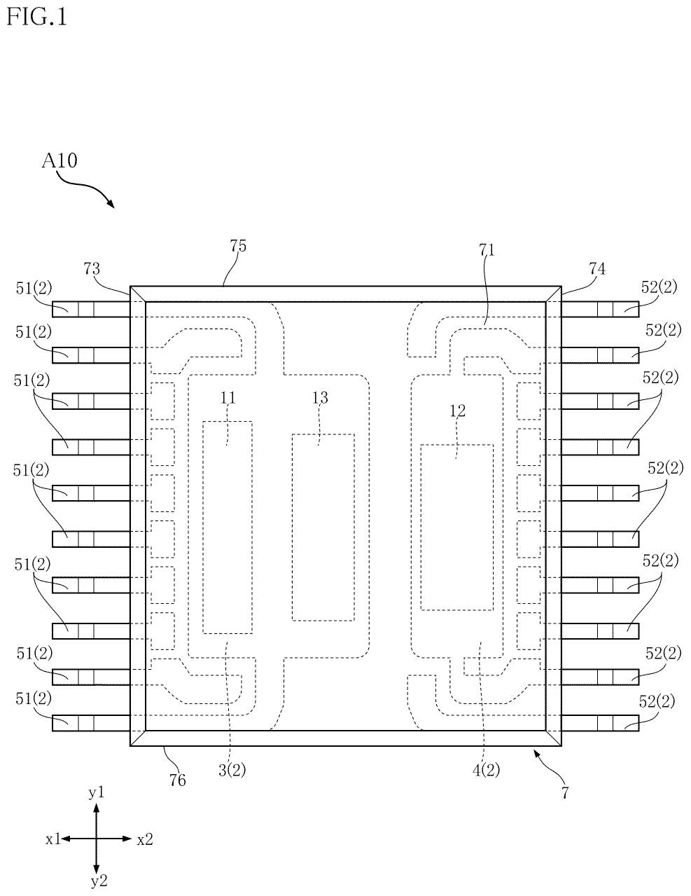

FIGS. 1 to 9 show an example of a semiconductor device of the present disclosure. The semiconductor device A10 of the present embodiment includes a first semiconductor element 11, a second semiconductor element 12, an insulating element 13, a conductive member 2, a plurality of wires 61 to 64, and a sealing resin 7. The conductive member 2 includes a first die pad 3, a second die pad 4, a plurality of first terminals 51, a plurality of second terminals 52, a plurality of pads 53 and 55, a pair of connecting portions 54, and a pair of connecting portions 56. The semiconductor device A10 is for surface mounting on a wiring board of an inverter device incorporated in an electric vehicle or a hybrid vehicle, for example. The semiconductor device A10 is not limited as to its usage and functionality. The semiconductor device A10 is provided in a small outline package (SOP). However, the package type of the semiconductor device A10 is not limited to SOP.

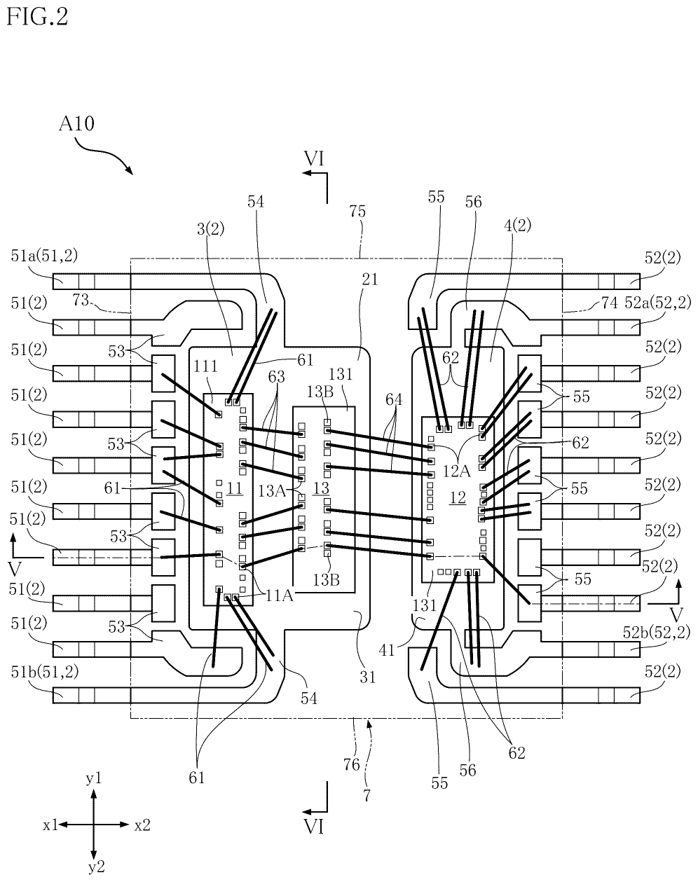

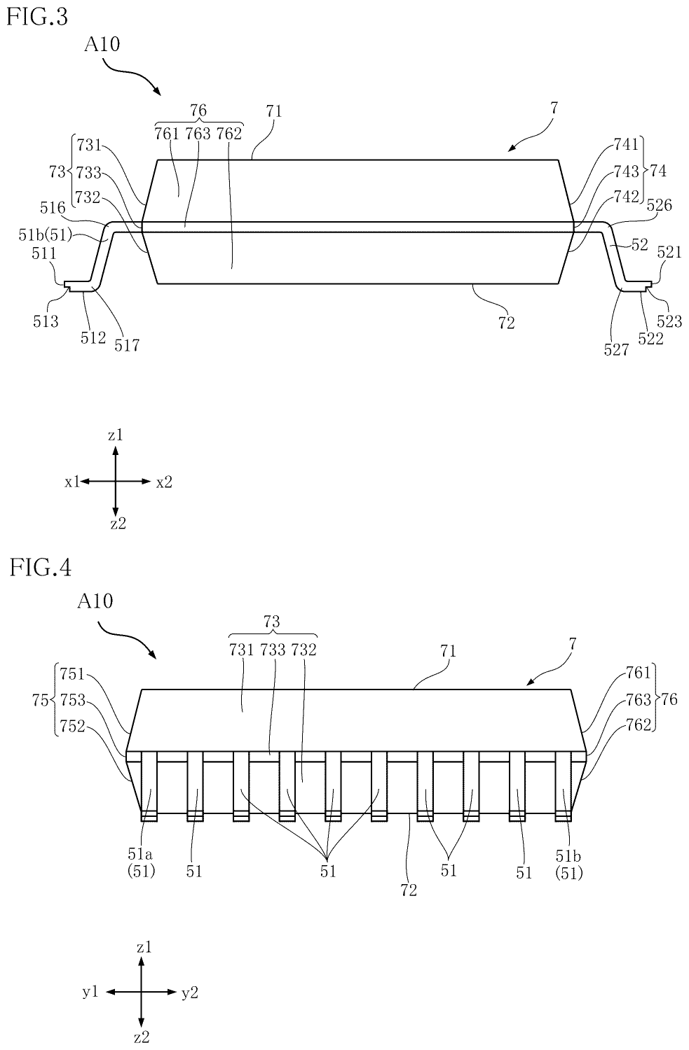

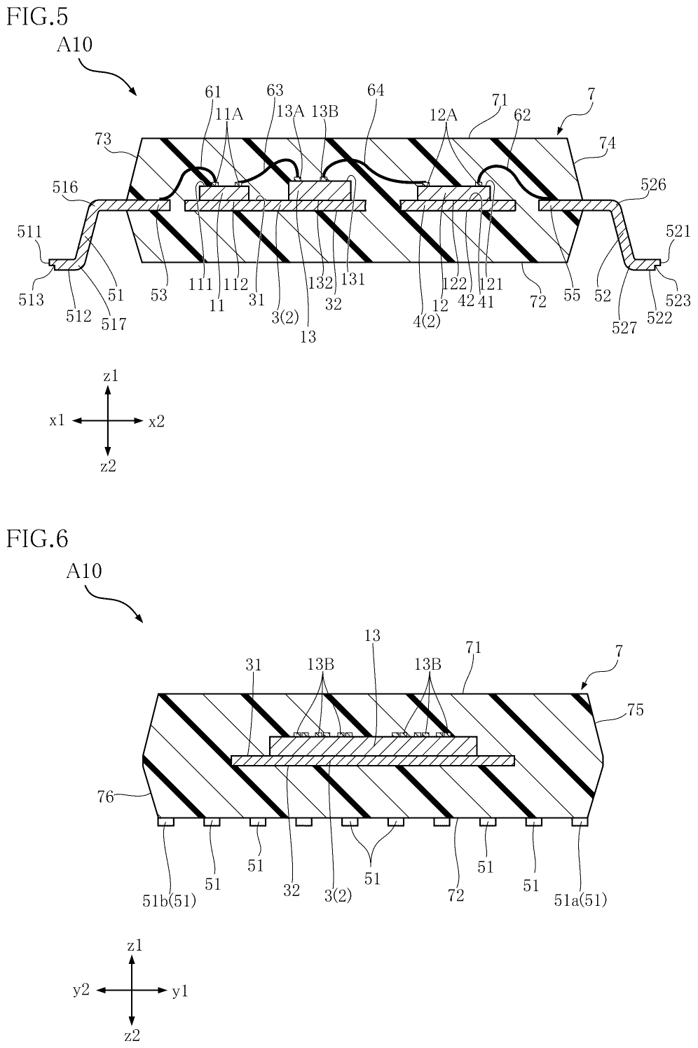

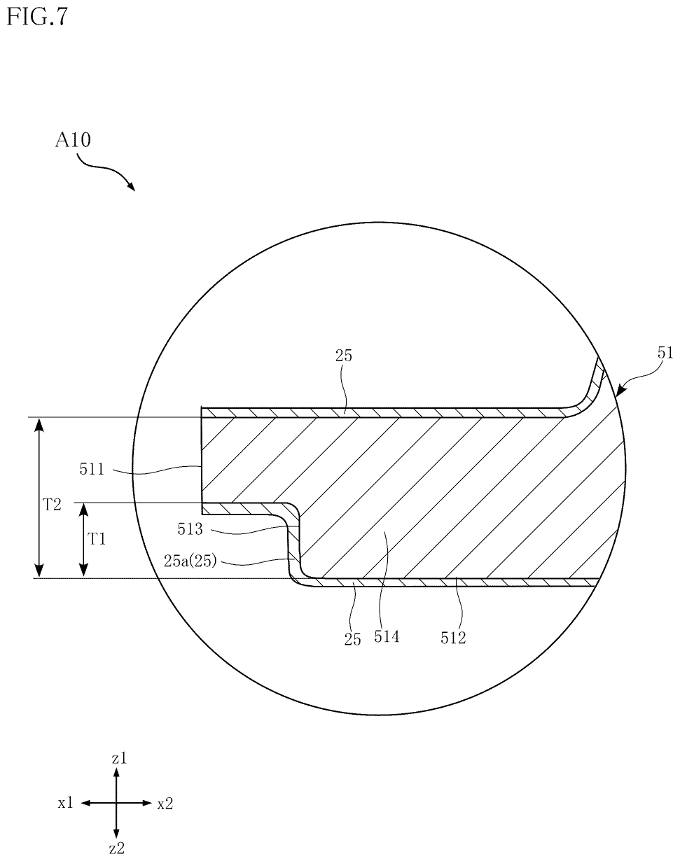

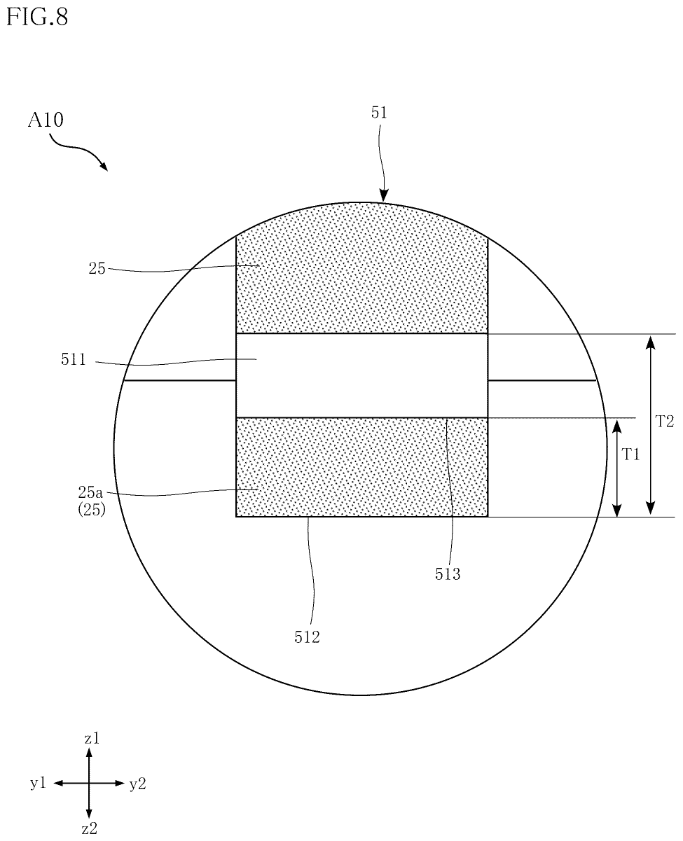

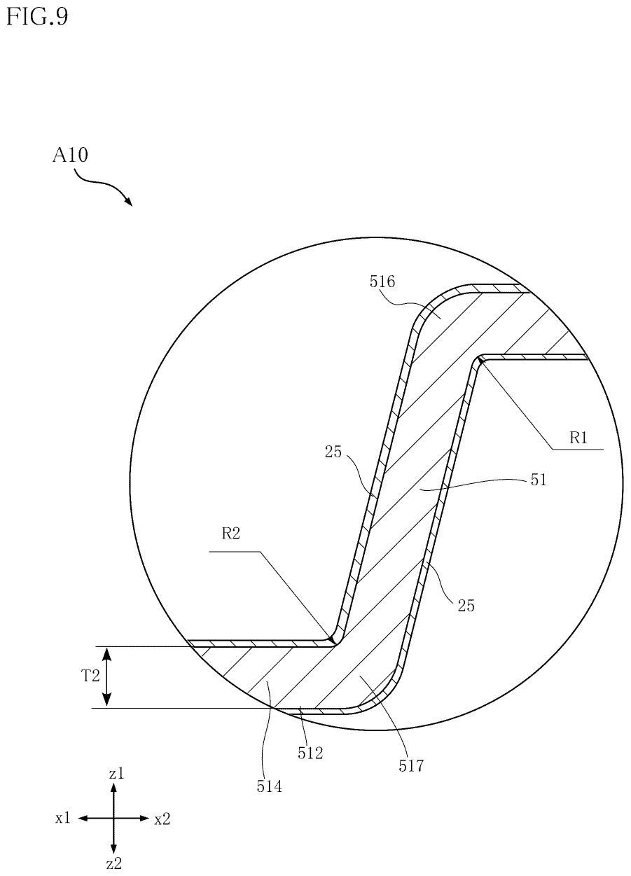

FIG. 1 is a plan view of the semiconductor device A10. FIG. 2 is a plan view of the semiconductor device A10. For the convenience of description, FIG. 2 shows the sealing resin 7 as transparent, and the outline of the sealing resin 7 is indicated by an imaginary line (dash-double dot line). FIG. 3 is a front view of the semiconductor device A10. FIG. 4 is a left-side view of the semiconductor device A10. FIG. 5 is a sectional view taken along line V-V in FIG. 2. FIG. 6 is a sectional view taken along line VI-VI in FIG. 2. FIG. 7 is a partial enlarged view of FIG. 5. FIG. 8 is a partial enlarged view of FIG. 4. FIG. 9 is a partial enlarged view of FIG. 5.

The semiconductor device A10 is rectangular as viewed in the thickness direction (in plan view). For the convenience of description, the thickness direction of the semiconductor device A10 is defined as the z direction, the direction parallel to one side of the semiconductor device A10 (the horizontal direction in FIGS. 1 and 2) is defined as the x direction, and the direction orthogonal to the z and x directions (the vertical direction in FIGS. 1 and 2) is defined as the y direction. Note that the shape and dimensions of the semiconductor device A10 are not limited.

The first semiconductor element 11, the second semiconductor element 12, and the insulating element 13 are integral components to the function of the semiconductor device A10.

As shown in FIG. 2, the first semiconductor element 11 is mounted on a portion of the conductive member 2 (a first die pad 3 described later). The first semiconductor element 11 is located at the center of the semiconductor device A10 in the y direction and offset toward the x1 side in the x direction. As viewed in the z direction, the first semiconductor element 11 has a rectangular shape elongated in the y direction. The first semiconductor element 11 is a control element. The first semiconductor element 11 includes a circuit for converting a control signal received from, for example, an ECU into a PWM control signal, a transmitting circuit for transmitting the PWM control signal to the second semiconductor element 12, and a receiving circuit for receiving an electrical signal from the second semiconductor element 12. The first semiconductor element 11 has an element obverse surface 111 and an element reverse surface 112 facing away from each other in the z direction. The element obverse surface 111 faces the z1 side in the z direction. The element obverse surface 122 faces the z2 side in the z direction. The element obverse surface 111 is provided with a plurality of electrodes 11A. The electrodes 11A are electrically connected to the circuits formed in the first semiconductor element 11.

As shown in FIG. 2, the second semiconductor element 12 is mounted on a portion of the conductive member 2 (a second die pad 4 described later). The second semiconductor element 12 is located at the center of the semiconductor device A10 in the y direction and offset toward the x2 side in the x direction. As viewed in the z direction, the second semiconductor element 12 has a rectangular shape elongated in the y direction. The second semiconductor element 12 is a drive element. The second semiconductor element 12 includes a receiving circuit for receiving a PWM control signal from the first semiconductor element 11, a circuit (gate driver) for generating a drive signal to drive a switching element (such as an IGBT or MOSFET) based on the received PWM control signal, and a transmitting circuit for transmitting an electrical signal to the first semiconductor element 11. The second semiconductor element 12 has an element obverse surface 121 and an element reverse surface 122 facing away from each other in the z direction. The element obverse surface 121 faces the z1 side in the z direction. The element reverse surface 122 faces the z2 side in the z direction. The element obverse surface 121 is provided with a plurality of electrodes 12A. The electrodes 12A are electrically connected to the circuits formed in the second semiconductor element 12.

As shown in FIG. 2, the insulating element 13 is mounted on a portion of the conductive member 2 (the first die pad 3) and located at the center of the semiconductor device A10 in the y direction. The insulating element 13 is located on the x2 side in the x direction with respect to the first semiconductor element 11, and on the x1 side in the x direction with respect to the second semiconductor element 12. In other words, the insulating element 13 is located between the first semiconductor element 11 and the second semiconductor element 12 in the x direction. As viewed in the z direction, the insulating element 13 has a rectangular shape elongated in the y direction. The insulating element 13 transmits PWM control signals and other electrical signals in an insulated state. The insulating element 13 receives a PWM control signal from the first semiconductor element 11 via the wires 63 and transmits the received PWM control signal to the second semiconductor element 12 via the wires 64 in an insulated state. Also, the insulating element 13 receives an electrical signal from the second semiconductor element 12 via the wires 64 and transmits the received electrical signal to the first semiconductor element 11 via the wires 63 in an insulated state. In short, the insulating element 13 electrically insulates the first semiconductor element 11 and the second semiconductor element 12 from each other, while allowing signal transmission between the first semiconductor element 11 and the second semiconductor element 12.

In the present embodiment, the insulating element 13 is an inductive insulating element, which transmits electrical signals in an insulated state through the inductive coupling of two inductors (coils). The insulating element 13 includes a substrate made of Si and inductors made of Cu on the substrate. The inductors include a transmitting-side inductor and an output-side inductor, and these inductors are stacked on top of each other in the thickness direction (the z direction) of the insulating element 13. A dielectric layer of, for example, SiO₂ is interposed between the transmitting-side inductor and the output-side inductor. The dielectric layer electrically insulates the transmitting-side inductor and the output-side inductor. While the insulating element 13 is an inductive insulating element in the present embodiment, the insulating element 13 may alternatively be a capacitive insulating element. One example of the capacitive insulating element is a capacitor.

The insulating element 13 has an element obverse surface 131 and an element reverse surface 132 facing away from each other in the z direction. The element obverse surface 131 faces the z1 side in the z direction. The element reverse surface 132 faces the z2 side in the z direction. The element obverse surface 131 is provided with a plurality of first electrodes 13A and a plurality of second electrodes 13B. Each of the first electrodes 13A and the second electrodes 13B is electrically connected either to the transmitting-side inductor or to the output-side inductor. The first electrodes 13A are aligned in the y direction at a location closer to the x1 side in the x direction in the insulating element 13. The second electrodes 13B are aligned in the y direction in the central region in the x direction.

The first semiconductor element 11 transmits a PWM control signal to the second semiconductor element 12 via the insulating element 13. Note that the first semiconductor element 11 may transmit a signal other than the PWM control signal to the second semiconductor element 12. The second semiconductor element 12 transmits an electrical signal to the first semiconductor element 11 via the insulating element 13. The information represented by the electrical signal transmitted from the second semiconductor element 12 to the first semiconductor element 11 is not limited.

Generally, an inverter device for, for example, a hybrid vehicle, includes as a motor driver circuit a half-bridge circuit composed of a low-side switching element and a high-side switching element that are connected in a totem-pole configuration. An insulated gate driver turns on only one of the low-side switching element and the high-side switching element at an any given time. In the high-voltage region, the source of the low-side switching element, as well as the reference voltage of the insulated gate driver that drives the low-side switching element, is connected to ground as the reference voltage. Consequently, the gate-to-source voltage is set relative to the ground. In contrast, the source of the high-side switching element, as well as the reference voltage of the insulated gate driver that drives the high-side switching element, is connected to the output node of the half-bridge circuit. The potential at the output node of the half-bridge circuit changes depending on which of the low-side switching element and the high-side switching element is on. Consequently, the reference potential of the insulated gate driver that drives the high-side switching element also changes. When the high-side switching element is on, the reference potential is equal to the voltage applied to the drain of the high-side switching element (e.g., 600 V or higher). The first semiconductor element 11 and the second semiconductor element 12 are connected to different grounds to ensure electrical isolation. When the semiconductor device A10 is used as an insulated gate driver for the high-side switching element, the second semiconductor element 12 may be subjected to a transient voltage of 600 V or higher relative to the ground of the first semiconductor element 11. To address the large potential difference between the first semiconductor element 11 and the second semiconductor element 12, the semiconductor device A10 includes the insulating element 13 that insulates the input-side circuit including the second semiconductor element 12 and the output-side circuit including the first semiconductor element 11 from each other. In short, the insulating element 13 provides electrical insulation between the input-side circuit that is held at lower potential and the output-side circuit that is held at higher potential.

The conductive member 2 forms conduction paths for connecting the first semiconductor element 11 and the second semiconductor element 12 of the semiconductor device A10 and the wiring board of an inverter device. The conductive member 2 is made of an alloy containing Cu, for example. The conductive member 2 is fabricated from a lead frame 81, which will be described later. The first semiconductor element 11, the second semiconductor element 12, and the insulating element 13 are mounted on the conductive member 2. As shown in FIG. 2, the conductive member 2 includes the first die pad 3, the second die pad 4, the first terminals 51, the second terminals 52, the pads 53 and 55, the pair of connecting portions 54, and the pair of connecting portions 56.

In the semiconductor device A10, the first die pad 3 is located in the central region in the y direction and offset in the x direction toward the x1 side. The second die pad 4 is spaced apart from the first die pad 3 toward the x2 side in the x direction.

As shown in FIGS. 2 and 5, the first semiconductor element 11 and the insulating element 13 are mounted on the first die pad 3. The first die pad 3 is electrically connected to the first semiconductor element 11 and is a component of the input-side circuit described above. As viewed in the z direction, the first die pad 3 is rectangular (or substantially rectangular), for example. The first die pad 3 has an obverse surface 31 and a reverse surface 32. As shown in FIGS. 5 and 6, the obverse surface 31 and the reverse surface 32 are spaced apart from each other in the z direction. The obverse surface 31 faces the z1 side, and the reverse surface 32 faces the z2 side. The first semiconductor element 11 and the insulating element 13 are mounted on the obverse surface 31.

As shown in FIGS. 6 and 8, the first semiconductor element 11 and the insulating element 13 are bonded to the obverse surface 31 of the first die pad 3 via a conductive bonding material 19. In the present embodiment, the conductive bonding material 19 is solder, for example. However, the conductive bonding material 19 is not limited to solder and may be metal paste or sintered metal.

As shown in FIGS. 2 and 5, the second semiconductor element 12 is mounted on the second die pad 4. The second die pad 4 is electrically connected to the second semiconductor element 12 and is a component of the output-side circuit described above. As viewed in the z direction, the second die pad 4 is rectangular (or substantially rectangular), for example. The second die pad 4 has an obverse surface 41 and a reverse surface 42. As shown in FIG. 5, the obverse surface 41 and the reverse surface 42 are spaced apart from each other in the z direction. The obverse surface 41 faces the z1 side, and the reverse surface 42 faces the z2 side. The second semiconductor element 12 is mounted on the obverse surface 41.

The first terminals 51 form conduction paths connecting the semiconductor device A10 and the wiring board of an inverter device when bonded to the wiring board. Each first terminal 51 is electrically connected to the first semiconductor element 11 and is a component of the input-side circuit described above. As shown in FIGS. 1, 2, and 4, the first terminals 51 are spaced apart from each other and aligned in the y direction at equal intervals. The first terminals 51 are located on the x1 side in the x direction with respect to the first die pad 3, protruding from the sealing resin 7 (a resin side surface 73 described later) toward the x1 side in the x direction. The first terminals 51 include a power supply terminal that receives voltage, a ground terminal, an input terminal for a control signal, an input terminal for other electrical signals, and an output terminal for other electrical signals. The semiconductor device A10 of the present embodiment includes 10 first terminals 51, but the number of the first terminals 51 is not limited. Also, input signals and output signals to and from the first terminals 51 are not specifically limited.

Each first terminal 51 is rectangular and elongated in the x direction and includes a portion exposed from the sealing resin 7 and a portion covered with the sealing resin 7. As shown in FIGS. 3 and 5, the exposed portion of each first terminal 51 is bent toward the z2 side in the z direction, forming a gull-wing profile.

As shown in FIGS. 7 and 8, each first terminal 51 has an end surface 511, a bottom surface 512, and a recess 513. The end surface 511 is located at the distal end of the first terminal 51 that protrudes from the sealing resin 7. The end surface 511 is a cut surface formed by cutting the lead frame in a cutting step, which will be described later. The bottom surface 512 faces the z2 side in the z direction. When the semiconductor device A10 is surface-mounted to the wiring board of an inverter device, the bottom surface 512 is bonded in face-to-face contact with the wiring board. The recess 513 is recessed from the end surface 511 toward the x2 side in the x direction and also from the bottom surface 512 toward the z1 side in the z direction. The recess 513 has a dimension T1 in the z direction, and a full-thickness portion 514 of the first terminal 51 where the bottom surface 512 is present has a dimension T2 in the z direction, where the dimension T1 is at least ¼ and at most ¾ of the dimension T2. The dimension of the recess 513 in the x direction is not specifically limited but may be substantially the same as the dimension T1. In the present embodiment, the recess 513 extends in the y direction across the entirety of the first terminal 51.

A plating layer 25 is applied to the entire portion of each first terminal 51 that is exposed from the sealing resin 7, except for the end surface 511. In FIG. 8, the plating layer 25 is represented with dots. Note that the region to be coated with the plating layer 25 is not limited. The plating layer 25 contains Sn, for example, but the material of the plating layer 25 is not limited. When the semiconductor device A10 is surface-mounted on the wiring board of an inverter device by soldering, the plating layer improves the adhesion of soler to the exposed portion and prevents erosion which may occur as a consequence of soldering. The plating layer 25 includes a recess plating section 25a. The recess plating section 25a is located on a recess 513. In a manufacturing step according to the present embodiment, the plating layer 25 is applied to the lead frame after recesses are formed, as described later. Thus, the recess plating section 25a is present on the entire recess 513. In a different example, the recess plating section 25a may be present at least on a portion of the recess 513.

As shown in FIGS. 3, 5, and 9, each first terminal 51 includes a first bend 516 and a second bend 517. The first bend 516 and the second bend 517 are portions of the first terminal 51 exposed from the sealing resin 7 and formed by bending. The first bend 516 bends toward the z2 side in the z direction. As shown in FIG. 9, the minimum radius of curvature R1 of the first bend 516 on its inside surface is equal to greater than the dimension T2 of the full-thickness portion 514 (the portion of the first terminal 51 where the bottom surface 512 is present) in the z direction (that is the thickness of the first terminal 51). The second bend 517 is located between the first bend 516 and the end surface 511 and bends toward the x1 side in the x direction. As shown in FIG. 9, the minimum radius of curvature R2 of the second bend 517 on its inside surface is also equal to or greater than the dimension T2 of the full-thickness portion 514 of the first terminal 51 in the z direction.

The plurality of first terminals 51 include a first terminal 51a and a first terminal 51b. The first terminal 51a is the first one of the first terminals 51 from the y1 side in the y direction. The first terminal 51b is the first one of the first terminals 51 from the y2 side in the y direction.

The plurality of pads 53 are connected to the respective first terminals 51 from the x2 side in the x direction, except for the first terminals 51a and 51b. The shapes of the pads 53 as viewed in the z direction are not limited. Each pad 53 has a flat (or substantially flat) upper surface (the surface facing the z1 side), and a wire 61 described later is bonded to the upper surface. The upper surfaces of the pads 53 may be plated. Plating may be applied to coat the upper surfaces of the pads 53 with a plating layer made of metal containing Ag, for example. The plating layer serves to increase the bonding strength of the wires 61 and also protect the lead frame 81 (described later) from the impacts during the process of bonding the wires 61. The entire surfaces of the pads 53 are covered with the sealing resin 7.

Each connecting portion 54 is connected to the first terminal 51a or 51b and the first die pad 3. Of the two connecting portions 54, the one connected to the first terminal 51a extends in the y direction and is connected at its y2-side end to the y1-side end of the first die pad 3 at a location around the center in the x direction. The other connecting portion 54, which is connected to the first terminal 51b, extends in the y direction and is connected at its y1-side end to the y2-side end of the first die pad 3 at a location around the center in the x direction. In this way, the first terminals 51a and 51b are connected to the first die pad 3 via the pair of connecting portions 54 and support the first die pad 3. Each pad 54 has a flat (or substantially flat) upper surface (the surface facing the z1 side), and wires 61 described later are bonded to the upper surface. Similarly to the upper surfaces of the pads 53, the upper surface of each connecting portion 54 may be coated with a plating layer (metal containing Ag, for example). The entire surfaces of the connecting portions 54 are covered with the sealing resin 7.

Similarly to the first terminals 51, the second terminals 52 form conduction paths connecting the semiconductor device A10 and the wiring board of an inverter device when bonded to the wiring board. Each second terminal 52 is electrically connected to the second semiconductor element 12 and is a component of the output-side circuit described above. As shown in FIGS. 1 and 2, the second terminals 52 are spaced apart from each other and aligned in the y direction at equal intervals. The second terminals 52 are located on the x2 side in the x direction with respect to the second die pad 4, protruding from the sealing resin 7 (a resin side surface 74 described later) in the x direction toward the x2 side. The second terminals 52 include a power supply terminal that receives voltage, a ground terminal, an output terminal for a drive signal, an input terminal for other electrical signals, and an output terminal for other electrical signals. The semiconductor device A10 of the present embodiment includes second terminals 52, but the number of the second terminals 52 is not limited. Also, input signals and output signals to and from the second terminals 52 are not specifically limited.

Each second terminal 52 is rectangular and elongated in the x direction and includes a portion exposed from the sealing resin 7 and a portion covered with the sealing resin 7. As shown in FIGS. 3 and 5, the exposed portion of each second terminal 52 is bent toward the z2 side in the z direction, forming a gull-wing profile.

As shown in FIG. 5, each second terminal 52 has an end surface 521, a bottom surface 522, and a recess 523. The end surface 521 is located at the distal end of the second terminal 52 that protrudes from the sealing resin 7. The end surface 521 is a cut surface formed by cutting the lead frame in a cutting step, which will be described later. The bottom surface 522 faces the z2 side in the z direction. When the semiconductor device A10 is surface-mounted to the wiring board of an inverter device, the bottom surface 522 is bonded in face-to-face contact with the wiring board. The recess 523 is recessed from the end surface 521 toward the x1 side in the x direction and also from the bottom surface 522 toward the z1 side in the z direction. Similarly to the dimensions of the first terminals 51, the dimension of the recess 523 in the z direction is at least ¼ and at most ¾ of the dimension in the z direction of the full-thickness portion 524 of the second terminal 52 where the bottom surface 522 is present. The dimension of the recess 523 in the x direction is not specifically limited but may be substantially the same as the dimension in the z direction. In the present embodiment, the recess 523 extends in the y direction across the entirety of the second terminal 52.

Similarly to the first terminals 51, a plating layer 25 is applied to the entire portion of each second terminal 52 that is exposed from the sealing resin 7, except for the end surface 521. Note that the region to be coated with the plating layer 25 is not limited to the example given above. Similarly to the recess 513, the recess plating section 25a is present on the recess 523.

As shown in FIGS. 3 and 5, each second terminal 52 includes a first bend 526 and a second bend 527. The first bend 526 and the second bend 527 are portions of the second terminal 52 exposed from the sealing resin 7 and formed by bending. The first bend 526 bends toward the z2 side in the z direction. The minimum radius of curvature of the first bend 526 on its inside surface is equal to greater than the dimension of the full-thickness portion 524 of the second terminal 52 in the z direction (that is the thickness of the second terminal 52). The second bend 527 is located between the first bend 526 and the end surface 521 and bends toward the x2 side in the x direction. The minimum radius of curvature of the second bend 527 on its inside surface is also equal to or greater than the dimension of the full-thickness portion 524 of the second terminal 52 in the z direction.

The plurality of second terminals 52 include a second terminal 52a and a second terminal 52b. The second terminal 52a is the second one of the second terminals 52 from the y1 side in the y direction. The second terminal 52b is the second one of the second terminals 52 from the y2 side in the y direction.

The plurality of pads 55 are connected to the respective second terminals 52 from the x1 side in the x direction, except for the second terminals 52a and 52b. The shapes of the pads 55 as viewed in the z direction are not limited. Each pad 55 has a flat (or substantially flat) upper surface (the surface facing the z1 side), and wires 62 described later are bonded to the upper surface. Similarly to the upper surfaces of the pads 53, the upper surface of each pad 55 may be coated with a plating layer (metal containing Ag, for example). The entire surfaces of the pads 55 are covered with the sealing resin 7.

Each connecting portion 56 is connected to the second terminal 52a or 52b and the second die pad 4. Of the two connecting portions 56, the one connected to the second terminal 52a is connected at its y2-side end to the y1-side end of the second die pad 4 at a location around the center in the x direction. The other connecting portion 56, which is connected to the second terminal 52b, is connected at its y1-side end to the y2-side end of the second die pad 4 at a location around the center in the x direction. In this way, the second terminals 52a and 52b are connected to the second die pad 4 via the pair of connecting portions 56 and supports the second die pad 4. Each pad 56 has a flat (or substantially flat) upper surface (the surface facing the z1 side), and wires 62 described later are bonded to the upper surface. Similarly to the upper surfaces of the pads 53, the upper surface of each connecting portion 56 may be coated with a plating layer (metal containing Ag, for example). The entire surfaces of the connecting portions 56 are covered with the sealing resin 7.

The shapes of the conductive member 2 is not limited to the example described above. For instance, the first die pad 3 may be supported by any first terminal 51. In other words, each connecting portion 54 may connect any of the first terminals 51 to the first die pad 3. The second die pad 4 may be supported by any second terminal 52. In other words, each connecting portion 56 may connect any of the second terminals 52 to the second die pad 4.

As shown in FIG. 2, the wires 61 to 64, together with the conductive member 2, form conduction paths used for the functions of the first semiconductor element 11, the second semiconductor element 12, and the insulating element 13. The wires 61 to 64 may be made of metal containing Au, Cu or Al, for example.

As shown in FIGS. 2 and 5, the wires 61 form conduction paths connecting the first semiconductor element 11 and the first terminals 51. The wires 61 electrically connect the first semiconductor element 11 to at least one of the first terminals 51. The wires 61 are components of the input-side circuit described above. As shown in FIG. 2, each wire 61 is electrically connected at one end to an electrode 11A of the first semiconductor element 11 and at the other end to a pad 53 or a connecting portion 54. The number of the wires 61 bonded to the pads 53 and the connecting portions 54 is not specifically limited.

As shown in FIGS. 2 and 5, the wires 62 form conduction paths connecting the second semiconductor element 12 and the second terminals 52. The wires 62 electrically connect the second semiconductor element 12 to at least one of the second terminals 52. The wires 62 are components of the output-side circuit described above. As shown in FIG. 2, each wire 62 is electrically connected at one end to an electrode 12A of the second semiconductor element 12 and at the other end to a pad 55 or a connecting portion 56. The number of the wires 62 bonded to the pads 55 and the connecting portions 54 is not specifically limited.

As shown in FIGS. 2 and 5, the wires 63 form a conduction path connecting the first semiconductor element 11 and the insulating element 13. The wires 63 electrically connect the first semiconductor element 11 and the insulating element 13 with each other. The wires 63 are components of the input-side circuit described above. As shown in FIG. 2, each wire 63 is electrically bonded to an electrode 11A of the first semiconductor element 11 and a first electrode 13A of the insulating element 13.

As shown in FIGS. 2 and 5, the wire 64 form a conduction path connecting the second semiconductor element 12 and the insulating element 13. The wires 64 electrically connect the second semiconductor element 12 and the insulating element 13 with each other. The wires 64 are components of the output-side circuit described above. As shown in FIG. 2, each wire 64 is electrically bonded to an electrode 12A of the second semiconductor element 12 and a second electrode 13B of the insulating element 13.

As shown in FIG. 1, the sealing resin 7 covers the first semiconductor element 11, the second semiconductor element 12, the insulating element 13, the first die pad 3, the second die pad 4, the connecting portion 54 and 56, the pads 53 and 55, the wires 61 to 64, a portion of each first terminal 51, and a portion of each second terminal 52. The sealing resin 7 is electrically insulating. The sealing resin 7 is made of a material containing a black epoxy resin, for example. The sealing resin 7 is rectangular as viewed in the z direction.

As shown in FIGS. 3 and 4, the sealing resin 7 has a resin top surface 71, a resin bottom surface 72, and resin side surfaces 73 to 76.

The resin top surface 71 and the resin bottom surface 72 are spaced apart from each other in the z direction. The resin top surface 71 and the resin bottom surface 72 face away from each other in the z direction. The resin top surface 71 is located on the z1 side in the z direction and faces the z1 side, which is the same side as the obverse surface 31 of the first die pad 3 faces. The resin bottom surface 72 is located on the z2 side in the z direction and faces the z2 side, which is the same side as the reverse surface 32 of the first die pad 3 faces. The resin top surface 71 and the resin bottom surface 72 are flat or (substantially flat).

Each of the resin side surfaces 73 to 76 extends between the resin top surface 71 and the resin bottom surface 72 in the z direction, connecting the resin top surface 71 and the resin bottom surface 72. The resin side surfaces 73 and 74 are spaced apart from each other in the x direction. The resin side surfaces 73 and 74 face away from each other in the x direction. The resin side surface 73 is located on the x1 side in the x direction, and the resin side surface 74 on the x2 side in the x direction. The resin side surfaces 75 and 76 are spaced apart from each other in the y direction and are each connected to the resin side surfaces 73 and 74. The resin side surfaces 75 and 76 face away from each other in the y direction. The resin side surface 75 is located on the y1 side in the y direction, and the resin side surface 76 on the y2 side in the y direction. As shown in FIG. 1, the resin side surface 73 is where portions of the first terminals 51 protrude. The resin side surface 74 is where portions of the second terminals 52 protrude.

As shown in FIGS. 3 and 4, the resin side surface 73 includes a resin first region 731, a resin second region 732, and a resin third region 733. The resin first region 731 is connected to the resin top surface 71 at one end in the z direction and to the resin third region 733 at the other end in the z direction. The resin first region 731 is inclined relative to the resin top surface 71 and the yz plane. The resin second region 732 is connected to the resin bottom surface 72 at one end in the z direction and to the resin third region 733 at the other end in the z direction. The resin second region 732 is inclined relative to the resin bottom surface 72 and the yz plane. The resin third region 733 is connected to the resin first region 731 at one end in the z direction and to the resin second region 732 at the other end in the z direction. The resin third region 733 is parallel to the yz plane. As viewed in the z direction, the resin third region 733 is located outside the resin top surface 71 and the resin bottom surface 72. The resin third region 733 is where the portion of each first terminal 51 protrudes.

As shown in FIG. 3, the resin side surface 74 includes a resin fourth region 741, a resin fifth region 742, and a resin sixth region 743. The resin fourth region 741 is connected to the resin top surface 71 at one end in the z direction and to the resin sixth region 743 at the other end in the z direction. The resin fourth region 741 is inclined relative to the resin top surface 71 and the yz plane. The resin fifth region 742 is connected to the resin bottom surface 72 at one end in the z direction and to the resin sixth region 743 at the other end in the z direction. The resin fifth region 742 is inclined relative to the resin bottom surface 72 and the yz plane. The resin sixth region 743 is connected to the resin fourth region 741 at one end in the z direction and to the resin fifth region 742 at the other end in the z direction. The resin sixth region 743 is parallel to the yz plane. As viewed in the z direction, the resin sixth region 743 is located outside the resin top surface 71 and the resin bottom surface 72. The resin sixth region 743 is where the portion of each second terminal 52 protrudes.

As shown in FIG. 4, the resin side surface 75 includes a resin seventh region 751, a resin eighth region 752, and a resin ninth region 753. The resin seventh region 751 is connected to the resin top surface 71 at one end in the z direction and to the resin ninth region 753 at the other end in the z direction. The resin seventh region 751 is inclined relative to the resin top surface 71 and the xz plane. The resin eighth region 752 is connected to the resin bottom surface 72 at one end in the z direction and to the resin ninth region 753 at the other end in the z direction. The resin eighth region 752 is inclined relative to the resin bottom surface 72 and the xz plane. The resin ninth region 753 is connected to the resin seventh region 751 at one end in the z direction and to the resin eighth region 752 at the other end in the z direction. The resin ninth region 753 is parallel to the xz plane. As viewed in the z direction, the resin ninth region 753 is located outside the resin top surface 71 and the resin bottom surface 72.

As shown in FIGS. 3 and 4, the resin side surface 76 includes a resin tenth region 761, a resin eleventh region 762, and a resin twelfth region 763. The resin tenth region 761 is connected to the resin top surface 71 at one end in the z direction and to the resin twelfth region 763 at the other end in the z direction. The resin tenth region 761 is inclined relative to both the resin top surface 71 and the xz plane. The resin eleventh region 762 is connected to the resin bottom surface 72 at one end in the z direction and to the resin twelfth region 763 at the other end in the z direction. The resin eleventh region 762 is inclined relative to the resin bottom surface 72 and the xz plane. The resin twelfth region 763 is connected to the resin tenth region 761 at one end in the z direction and to the resin eleventh region 762 at the other end in the z direction. The resin twelfth region 763 is parallel to the xz plane. As viewed in the z direction, the resin twelfth region 763 is located outside the resin top surface 71 and the resin bottom surface 72.

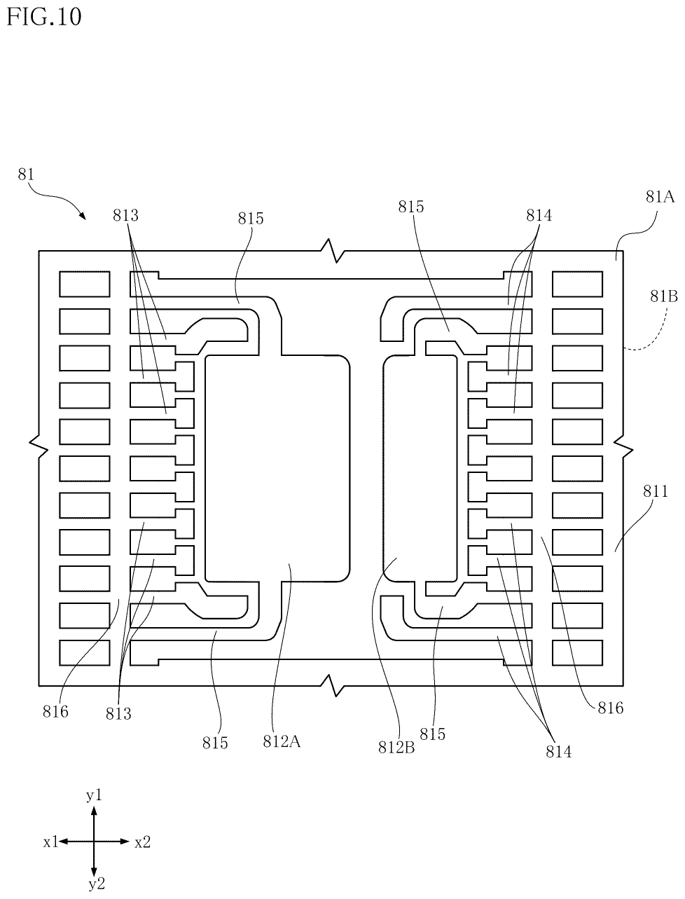

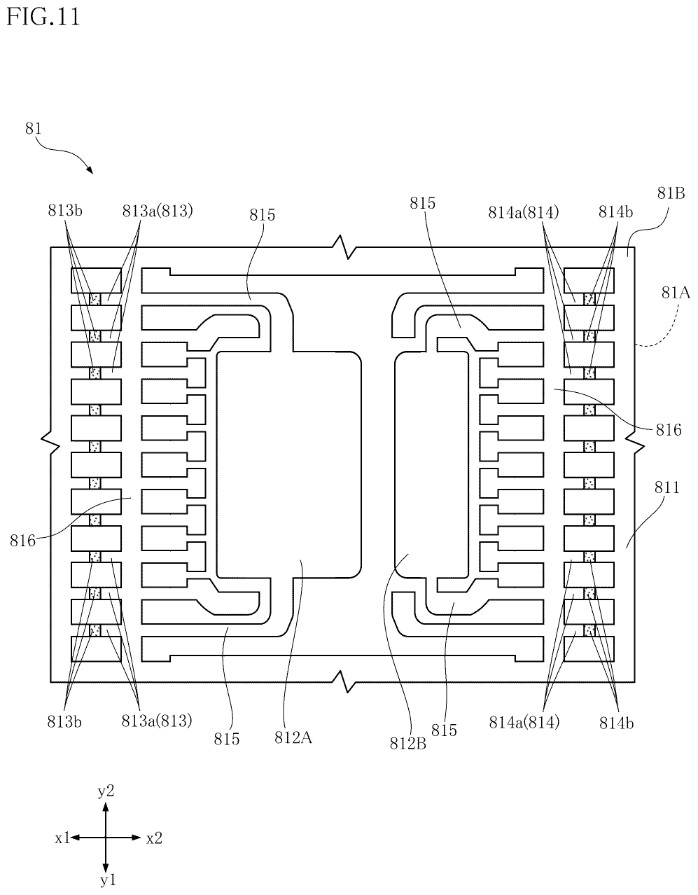

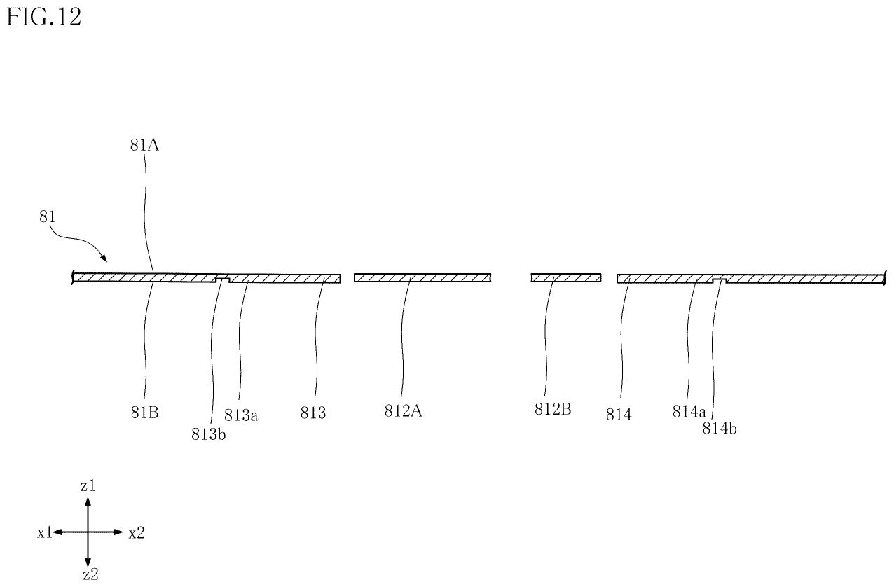

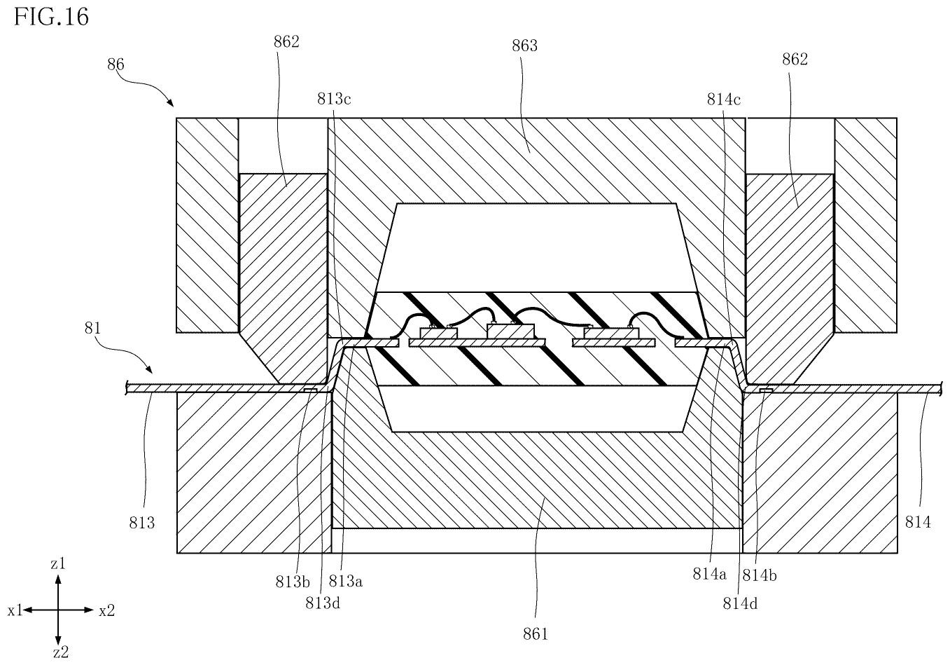

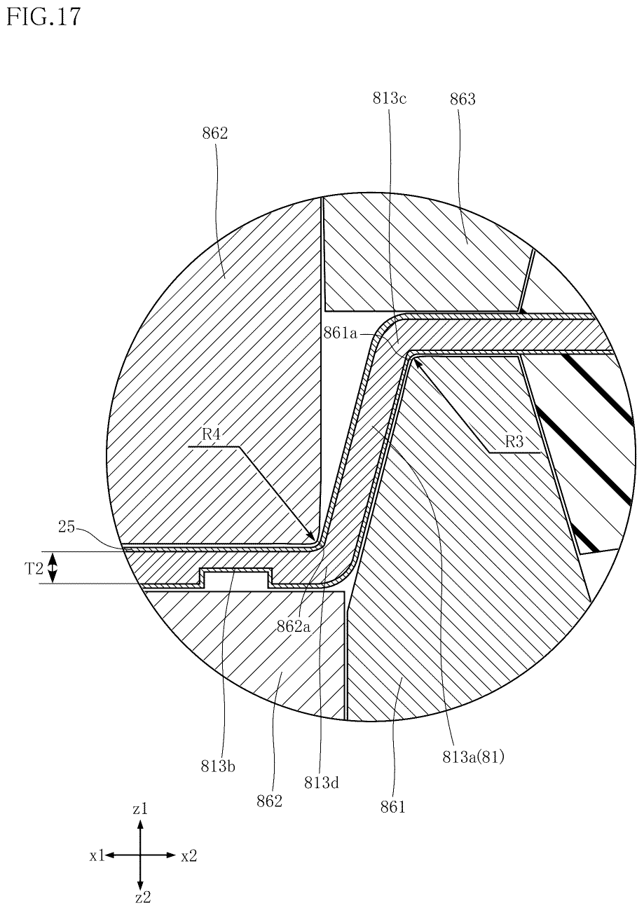

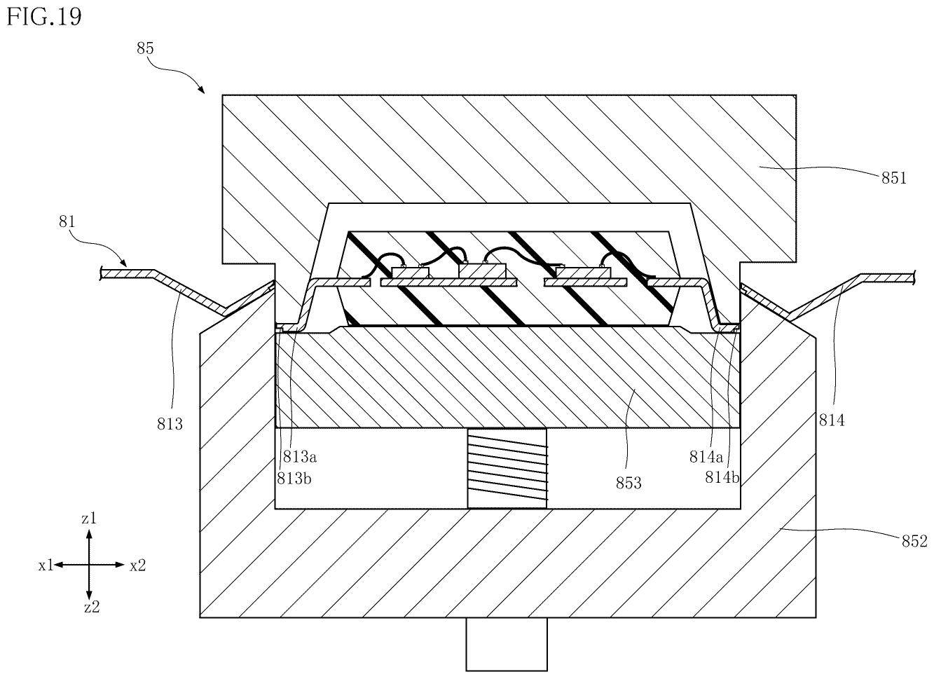

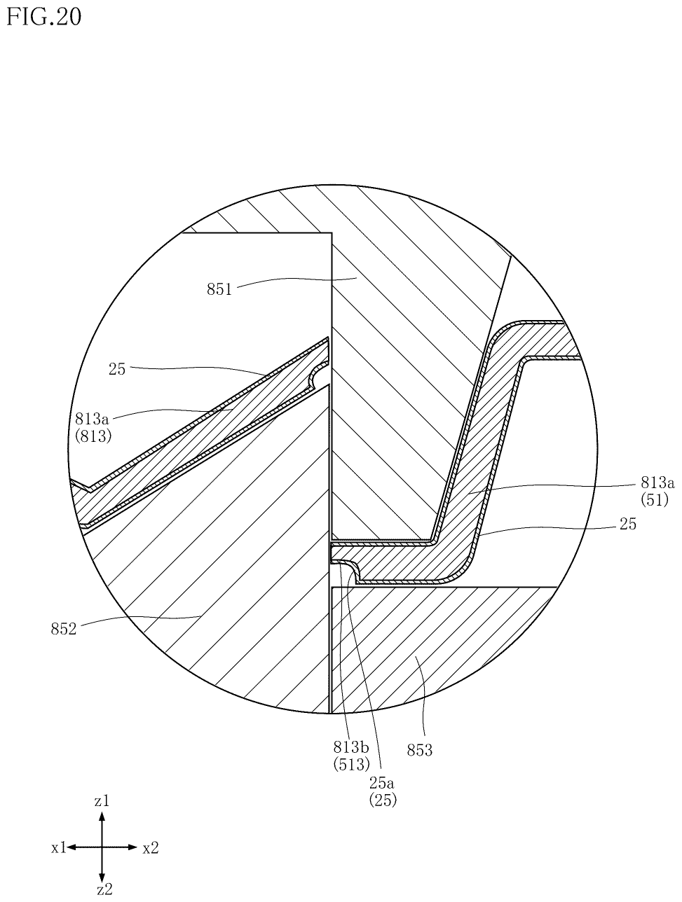

Next, an example of a method for manufacturing a semiconductor device A10 is described with reference to FIGS. 10 to 20. FIGS. 10, 13 and 14 are plan view each illustrating a step of the method for manufacturing a semiconductor device A10. FIG. 11 is a bottom view illustrating a step of the method for manufacturing a semiconductor device A10. FIGS. 12, 15, 16, 18 and 19 are sectional views each illustrating a step of the method for manufacturing a semiconductor device A10: the section shown in each sectional view corresponds to a section taken along line V-V in FIG. 2. FIG. 17 is an enlarged view showing a portion of FIG. 16. FIG. 20 is an enlarged view showing a portion of FIG. 19. The x, y and z directions in these figures correspond to those in FIGS. 1 to 8.

First, a lead frame 81 is prepared as shown FIGS. 10 to 12. The lead frame 81 is substantially a plate. In the present embodiment, the base material of the lead frame 81 is Cu. The lead frame 81 can be formed by applying etching to a metal plate or by applying punching to a metal plate. In the present embodiment, the lead frame 81 is formed by etching. The lead frame 81 has an obverse surface 81A and a reverse surface 81B spaced apart in the z direction. The lead frame 81 is composed of an outer frame 811, a first die pad 812A, a second die pad 812B, a plurality of first leads 813, a plurality of second leads 814, a plurality of connecting portions 815, and dam bars 816. The outer frame 811 and the dam bars 816 are not portions forming the semiconductor device A10. The first die pad 812A will be formed into a first die pad 3. The second die pad 812B will be formed into a second die pad 4. The first leads 813 will be formed into a plurality of first terminals 51 and a plurality of pads 53. The second leads 814 will be formed into a plurality of second terminals 52 and a plurality of pads 55. The connecting portions 815 will be formed into a pair of connecting portions 54 and a pair of connecting portions 56.

As shown in FIGS. 11 and 12, each first lead 813 has a recess 813b in a terminal portion 813a that will be formed into a first terminal 51. Each second lead 814 has a recess 814b in a terminal portion 814a that will be formed into a second terminal 52. In FIG. 11, the recesses 813b and 814b are represented with dots. The recesses 813b and 814b are recessed from the reverse surface 81B toward the z1 side in the z direction. The recesses 813b and 814b can be formed by half-etching, for example. However, the method for forming the recesses 813b and 814b is not limited. Each recess 813b extends across the entity of the corresponding terminal portion 813a in the y direction. Each recess 814b extends across the entity of the corresponding terminal portion 814a in the y direction.

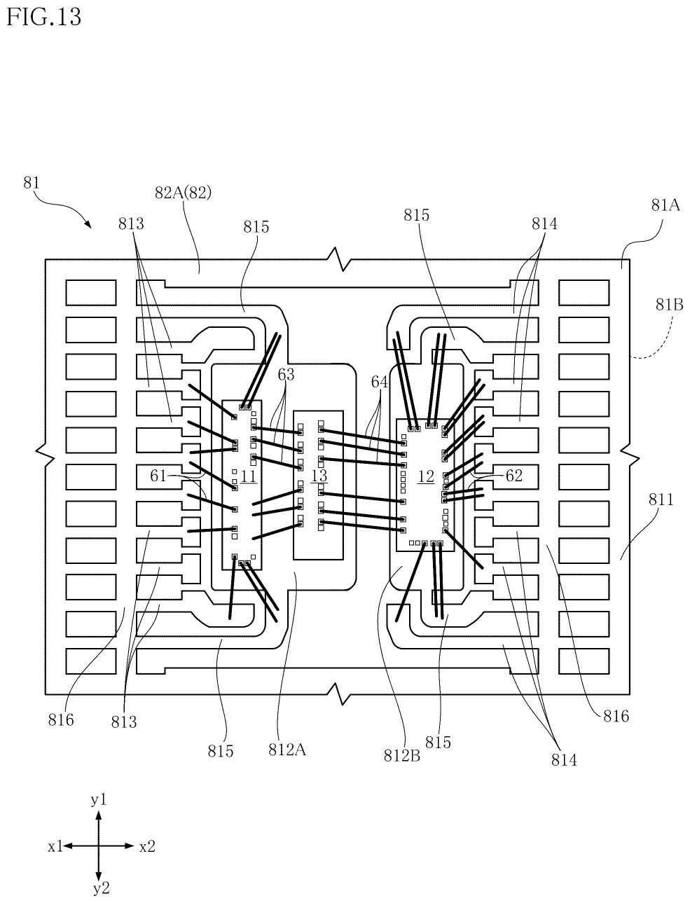

Subsequently, as shown in FIG. 13, the first semiconductor element 11 and the insulating element 13 are attached to the first die pad 812A by die bonding, and the second semiconductor element 12 is attached to the second die pad 812B by die bonding. Subsequently, a plurality of wires 61 to 64 are formed by wire bonding.

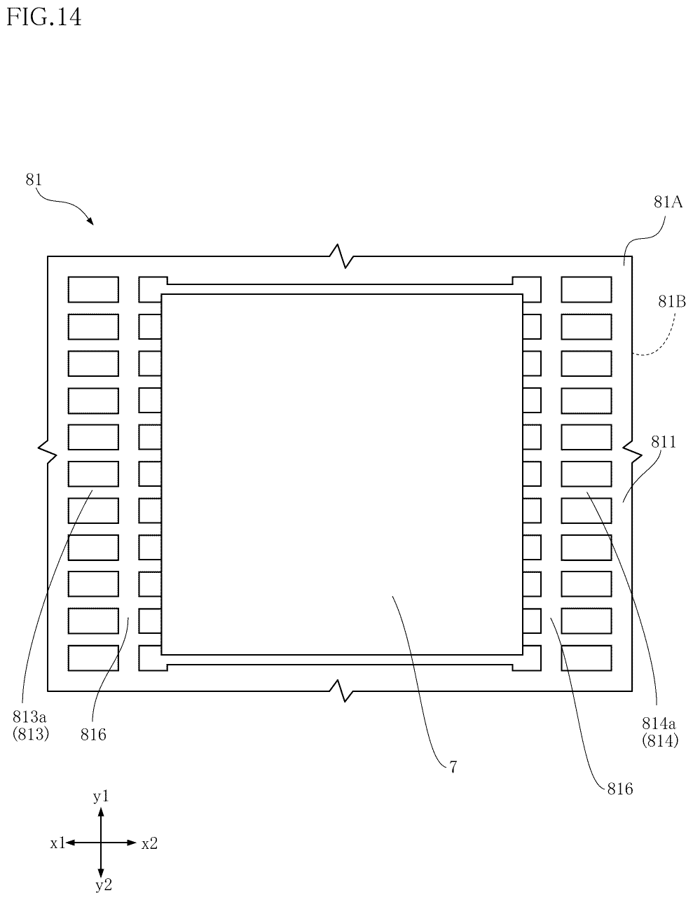

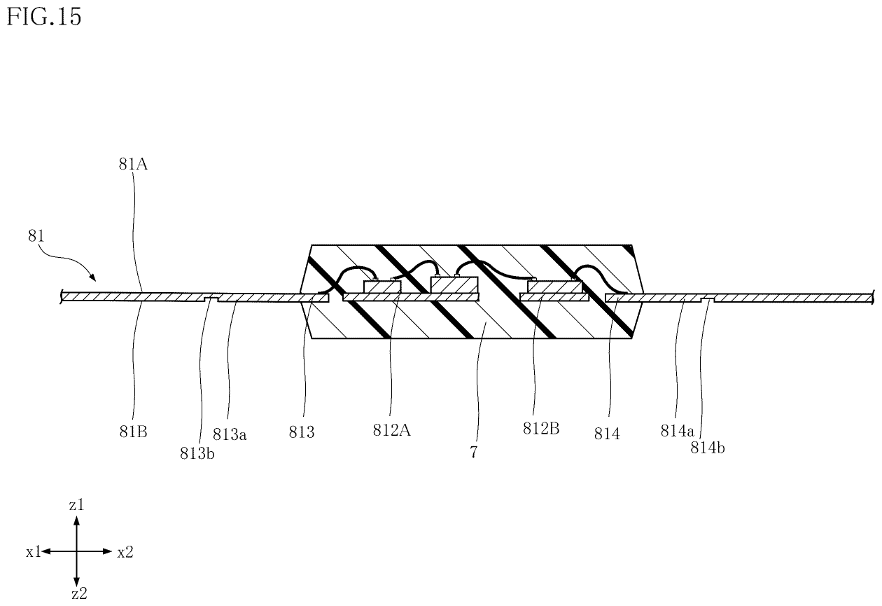

Subsequently, a sealing resin 7 is formed as shown in FIGS. 14 and 15. The sealing resin 7 is formed by transfer molding. This step begins with placing the lead frame 81 into a mold having a plurality of cavities. Here, a specific portion of the lead frame 81 is placed into a cavity. This portion will form a portion of the conductive member 2 covered with the sealing resin 7 in the semiconductor device A10. Then, molten resin is injected from a pot through the runners to fill the cavities. After the molten resin in the cavity solidifies to form the sealing resin 7, resin burrs located outside the cavity are removed using, for example, high-pressure water. This completes the formation of the sealing resin 7.

Subsequently, a plating layer 25 is formed to coat the portions of the lead frame 81 exposed from the sealing resin 7. The plating layer 25 thus formed is present on the terminal portions 813a and 814a. The plating layer 25 is also present on the recesses 813b of the terminal portions 813a and the recesses 814b of the terminal portions 814a.

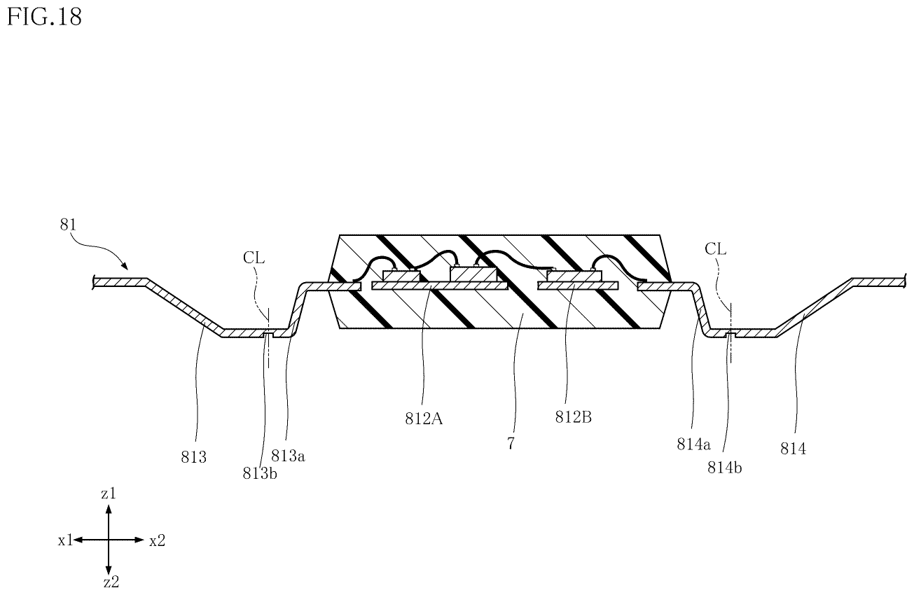

Subsequently, the lead frame 81 is bent as shown in FIGS. 16 and 17. In the bending step, a forming tool 86 is used to bend the terminal portions 813a and 814a. The forming tool 86 includes a forming die 861, a forming punch 862, and a stripper block 863. The lead frame 81 covered with the sealing resin 7 is placed on the forming die 861. The stripper block 863 clamps and secures the terminal portions 813a and 814a against the forming die 861. Then, the forming punch 862 is moved in the z direction toward the z2 side to bend the terminal portions 813a and 814a. As a result, the terminal portions 813a and 814a are bent toward the z2 side in the z direction, forming a gull-wing profile as shown in FIG. 18.

As shown in FIG. 17, the forming die 861 has a shoulder 861a. The terminal portion 813a of the lead frame 81 is bent at the portion pressed against the shoulder 861a, and this portion forms a first bend 813c that corresponds to the first bend 516. The shoulder 861a of the forming die 861 has the minimum radius of curvature R3 that is equal to or greater than the thickness dimension T2 of the lead frame 81. Consequently, the minimum radius of curvature R1 of the first bend 813c on its inside surface (see FIG. 9) is equal to or greater than the thickness dimension T2 of the lead frame 81. In addition, the forming punch 862 has a shoulder 862a, and the terminal portion 813a is also bent at a portion pressed against the shoulder 862a. This portion forms a second bend 813d that corresponds to the second bend 517. The shoulder 862a of the forming punch 862 has the minimum radius of curvature R4 that is equal to or greater than the thickness dimension T2 of the lead frame 81. Consequently, the minimum radius of curvature R2 of the second bend 813d on its inside surface (see FIG. 9) is equal to or greater than the thickness dimension T2 of the lead frame 81. The terminal portion 814a is bent similarly to the terminal portion 813a to form a first bend 814c and a second bend 814d. The first bend 814c corresponds to the first bend 526, and the second bend 814d corresponds to the second bend 527. The minimum radius of curvature of each of the first bend 814c and the second bend 814d on the inside surface is also equal to or greater than the thickness dimension T2 of the lead frame 81.

Subsequently, the lead frame 81 is cut as shown in FIGS. 19 and 20. In this step, a cutting tool 85 is used to cut the terminal portions 813a and 814a along the cutting lines CL shown in FIG. 18. One of the cutting lines CL extends in the y direction to intersect the respective recesses 813b. Another cutting line CL extends in the y direction to intersect the respective recesses 814b. In the present embodiment, the cutting tool 85 uses an upper cut method in which the terminal portions 813a and 814a are cut from the z2 side in the z direction. The cutting tool 85 includes a cutting die 851, a cutting punch 852, and a stripper block 853. The lead frame 81, which is covered with the sealing resin 7, is placed on the stripper block 853. The cutting die 851 clamps and secures the terminal portions 813a and 814a against the stripper block 853. The cutting punch 852 is fixed, so that the cutting die 851 and the stripper block 853 are moved in the z direction toward the z2 side. That is, the cutting punch 852 moves in the z direction relative to the cutting die 851 and the stripper block 853, from the z2 side toward the z1 side. The cutting punch 852 thus cuts the terminal portions 813a and 814a sandwiched between the cutting punch 852 and the cutting die 851, separating the portions that extend beyond the cutting die 851. That is, as a result of cutting the terminal portions 813a, the first terminals 51 are separated from the respective first leads 813. Similarly, as a result of cutting the terminal portions 814a, the second terminals 52 are separated from the respective second leads 814. This ensures that each first terminal 51 includes a portion of a recess 813b, which serves as a recess 513, and each second terminal 52 includes a portion of a recess 814b, which serves as a recess 523.

The semiconductor device A10 is completed through the steps described above.

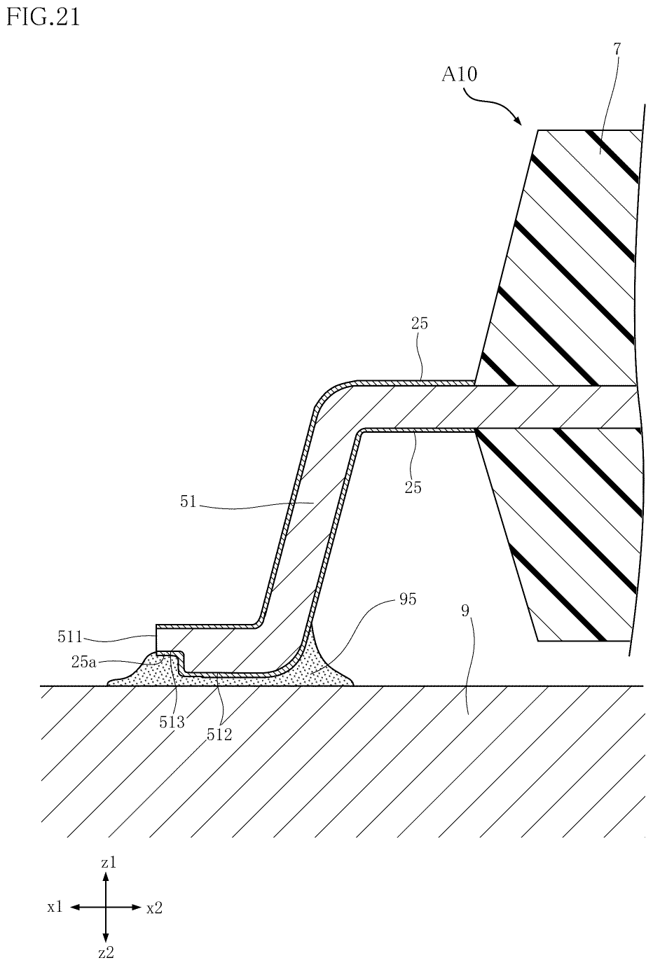

Next, the process of mounting a semiconductor device A10 to a wiring board will be described. FIG. 21 is a partial enlarged sectional view showing the semiconductor device A10 mounted on a wiring board 9.

As shown in FIG. 21, the semiconductor device A10 is placed on the wiring board 9, and the first terminals 51 and the second terminals 52 are bonded by solder 95 to the wiring (not shown) formed on the wiring board 9. In this process, since the recess 513 of each first terminal 51 is coated with a recess plating section 25a, solder 95 adheres to the recesses 513 and form solder fillets. Similarly, the recess 523 of each second terminal 52 is coated with a recess plating section 25a, so that solder 95 adheres to the recesses 523 and form solder fillets.

Next, the effects of the semiconductor device A10 will be described.

In the present embodiment, each first terminal 51 has a recess 513. The recess 513 is recessed from the end surface 511 toward the x2 side in the x direction and also from the bottom surface 512 toward the z1 side in the z direction. The recess 513 is coated with the recess plating section 25a. When the semiconductor device A10 is joined to a wiring board 9 by bonding the first terminals 51 to the wiring board 9 with solder 95, the presence of the recess plating section 25a ensures that the solder 95 adheres to the recess 513 and form a solder fillet. Similarly, the solder 95 adheres to the recess 523 of each second terminal 52 and forms a solder fillet. The semiconductor device A10 thus prevents defective soldering when mounted on a wiring board 9.

In the present embodiment, the z-direction dimension T1 of each recess 513 is at least ¼ and at most ¾ of the z-direction dimension T2 of the full-thickness portion 514. Similarly, the z-direction dimension of each recess 523 is at least ¼ and at most ¾ of the z-direction dimension of the full-thickness portion 524. The semiconductor device A10 ensures that the lead frame 81 formed with the recesses 813b and 814b maintains a sufficient strength during the manufacturing and that the solder 95 adheres to the recesses 513 and 523 to form solder fillets at the time of mounting.

In the present embodiment, each recess 513 extends across the entire first terminal 51 in the y direction. Consequently, compared with the case where a recess 513 extends in a limited portion of the first terminal 51 in the y direction, the solder 95 adhered to the recess 513 forms a solder fillet that is more widely spread in the y direction. The same applies to the recesses 523 as well. With this configuration, the semiconductor device A10 more reliably prevents defective soldering when it is mounted on a wiring board 9.

In the present embodiment, each first terminal 51 includes a first bend 516 with a minimum radius of curvature R1 on its inside surface that is equal to or greater than the z-direction dimension T2 of the full-thickness portion 514 of the first terminal 51. Compared with the case where the minimum radius of curvature R1 is less than the dimension T2, the first terminal 51 is less prone to cracking or plating rupturing at the time of bending the first bend 516. Each first terminal 51 additionally includes a second bend 517 with a minimum radius of curvature R2 on its inside surface that is equal to or greater than the z-direction dimension T2 of the full-thickness portion 514 of the first terminal 51. Compared with the case where the minimum radius of curvature R2 is less than the dimension T2, the first terminal 51 is less prone to cracking or plating rupturing at the time of bending the second bend 517. Similarly, each second terminal 52 includes a first bend 526 and a second bend 527 with a minimum radius of curvature on its inside surface that is equal to or greater than the z-direction dimension of the full-thickness portion 524 of the second terminal 52. Consequently, the second terminal 52 is less prone to cracking or plating rupturing at the time of bending the first bend 526 and the second bend 527.

In the present embodiment, the forming die 861 of the forming tool 86 has a shoulder 861a with a minimum radius of curvature R3 that is equal to or greater than the thickness dimension T2 of the lead frame 81. With this forming tool 86, each first bend 813c (516) is formed with a minimum radius of curvature R1 that is equal to or greater than the thickness dimension T2 of the lead frame 81. In addition, the forming punch 862 has a shoulder 862a with a minimum radius of curvature R4 that is equal to or greater than the thickness dimension T2 of the lead frame 81. With this forming tool 86, each second bend 813d (517) is formed with a minimum radius of curvature R2 that is equal to or greater than the thickness dimension T2 of the lead frame 81. The forming tool 86 also ensures that each of the first bend 814c (526) and the second bend 814d (527) is formed with a minimum radius of curvature that is equal to or greater than the thickness dimension T2 of the lead frame 81.

Note that the present embodiment describes the case where the cutting tool 85 uses an upper cut method but this is not a limitation. The cutting tool 85 using a down-cut method may be employed to cut the terminal portions 813a and 814a from the z1 side in the z direction. Note that the down-cut method may result in burrs projecting in the z direction toward the z2 side. However, since the bonding of the first terminal 51 (second terminal 52) has the recesses 513 (the recesses 523), such burrs will not interfere with joining the terminal to the wiring board 9.

Note that the semiconductor device A10 are not specifically limited regarding the packaging type, the type and number of semiconductor elements included, the shape and arrangement of the conductive member 2, the number of terminals, and so on. The semiconductor device A10 may have any configuration provided that the device includes terminals protruding from the sealing resin 7 and is suitable for surface-mounted on a wiring board.

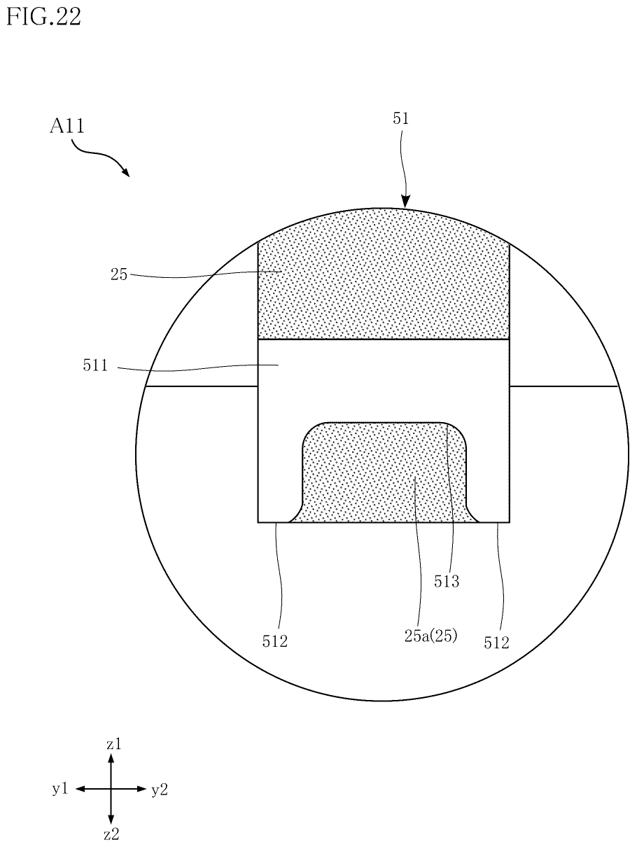

FIGS. 22 to 27 show variations of the semiconductor device A10 according to the first embodiment. In these figures, components that are identical or similar to those of the above-described embodiment are given the same reference numerals as those in the above-described embodiment and overlapping explanations of such components are omitted.

### First Variation:

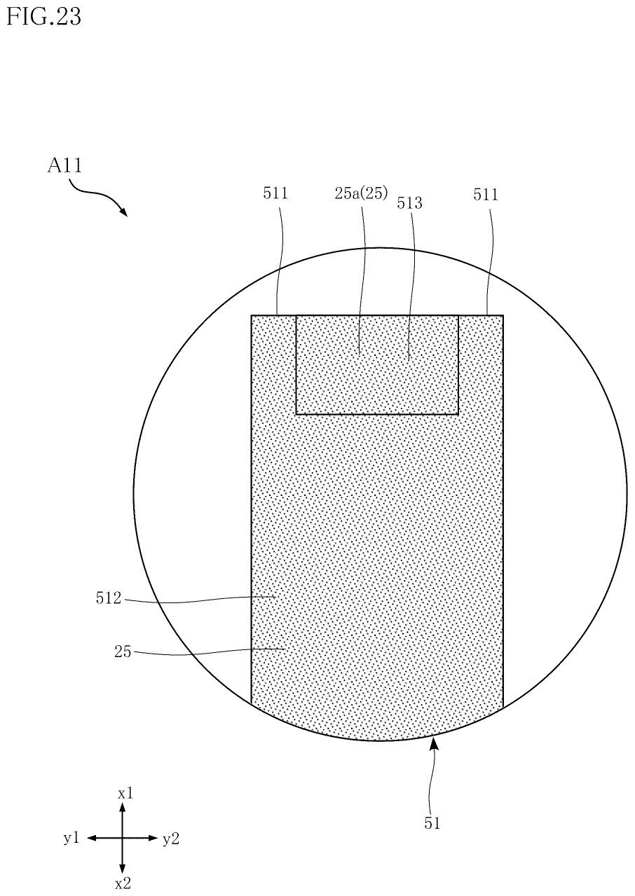

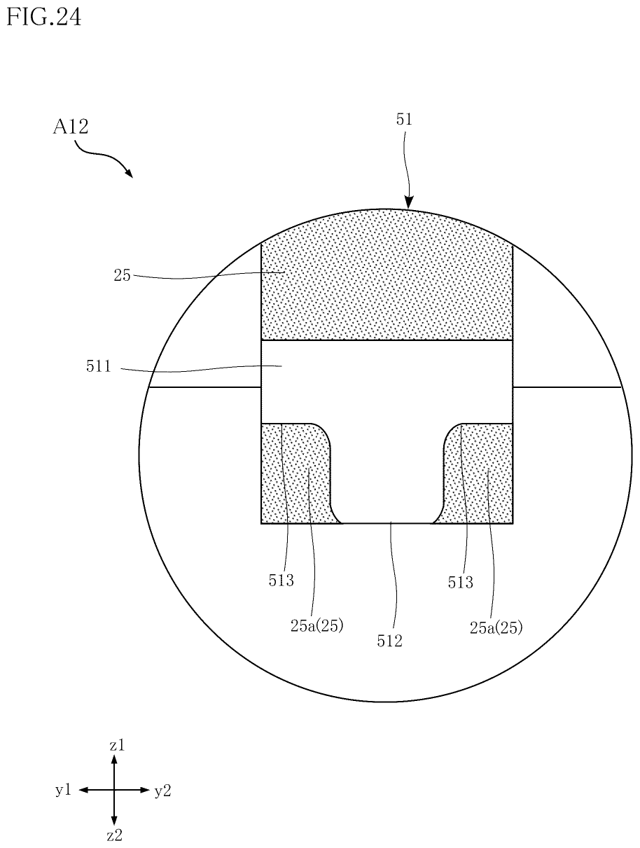

FIGS. 22 and 23 are views for illustrating a semiconductor device A11 according to a first variation of the first embodiment. FIG. 22 is a partial enlarged left-side view of the semiconductor device A11 and corresponds to FIG. 8. FIG. 23 is a partial enlarged bottom view of a first terminal 51 as seen in the z direction from the z2 side. In FIGS. 22 and 23, the plating layer 25 is represented with dots. The semiconductor device A11 differs from the semiconductor device A10 in the region of each recess 513 formed. In this variation, each recess 513 is formed only in a central portion of a first terminal 51 in the y direction. Thus, the bottom surface 512 is contiguous with the end surface 511 at the portions opposite in the y direction across the recess 513. The recess 513 of this variation is formed by providing each terminal portion 813a of the lead frame 81 with a recess 813b that extends only in the central portion in the y direction, rather than across the entire length in the y direction.

### Second Variation:

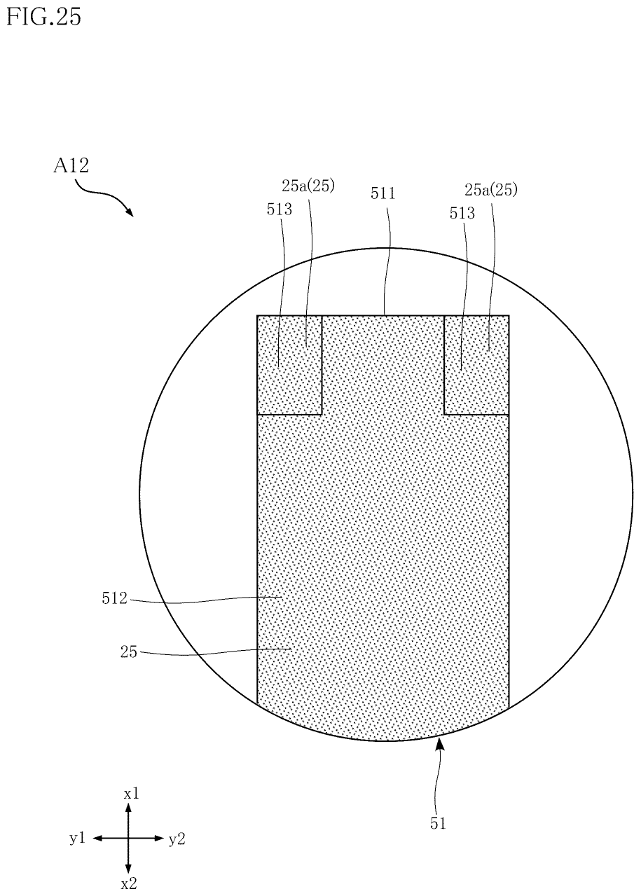

FIGS. 24 and 25 are views for illustrating a semiconductor device A12 according to a second variation of the first embodiment. FIG. 24 is a partial enlarged left-side view of the semiconductor device A12 and corresponds to FIG. 8. FIG. 25 is a partial enlarged bottom view of a first terminal 51 as seen in the z direction from the z2 side. In FIGS. 24 and 25, the plating layer 25 is represented with dots. The semiconductor device A12 differs from the semiconductor device A10 in the region of each recess 513 formed. Each recess 513 of this variation includes two separate portions at the opposite ends of a first terminal 51 in the y direction. Thus, the bottom surface 512 is contiguous with the end surface 511 at the central portion of the recess 513 in the y direction. The recess 513 of this variation is formed by providing each terminal portion 813a of the lead frame 81 with a recess 813b having two portions opposite in the y direction, rather than across the entire terminal portion 813a in the y direction.

As can be understood from the first and second variations, the location and region of each recess 513 are not limited. However, for the purpose of preventing defective soldering at the time of mounting the semiconductor device to a wiring board 9, it is preferable that each recess 513 extends across the entire first terminal 51 in the y direction as in the semiconductor device A10.

### Third Variation:

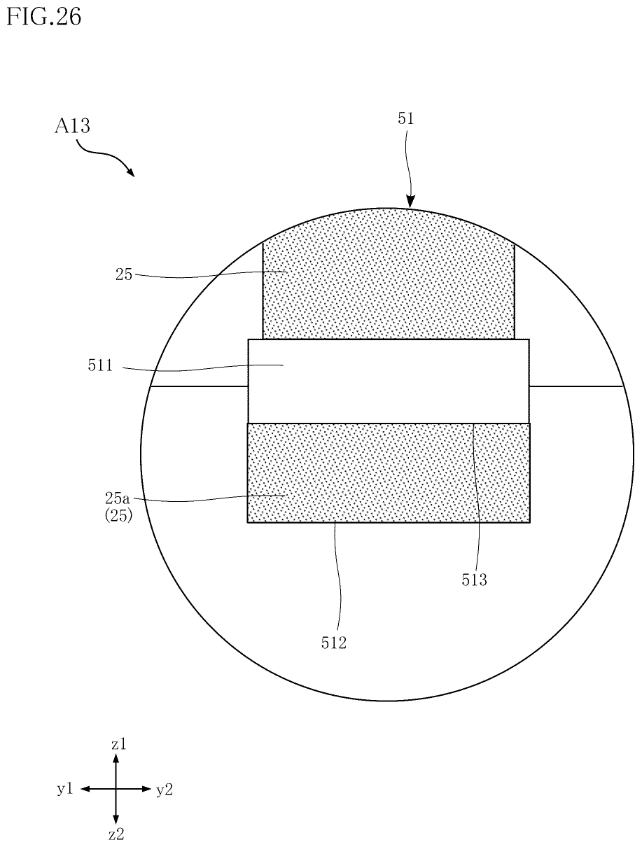

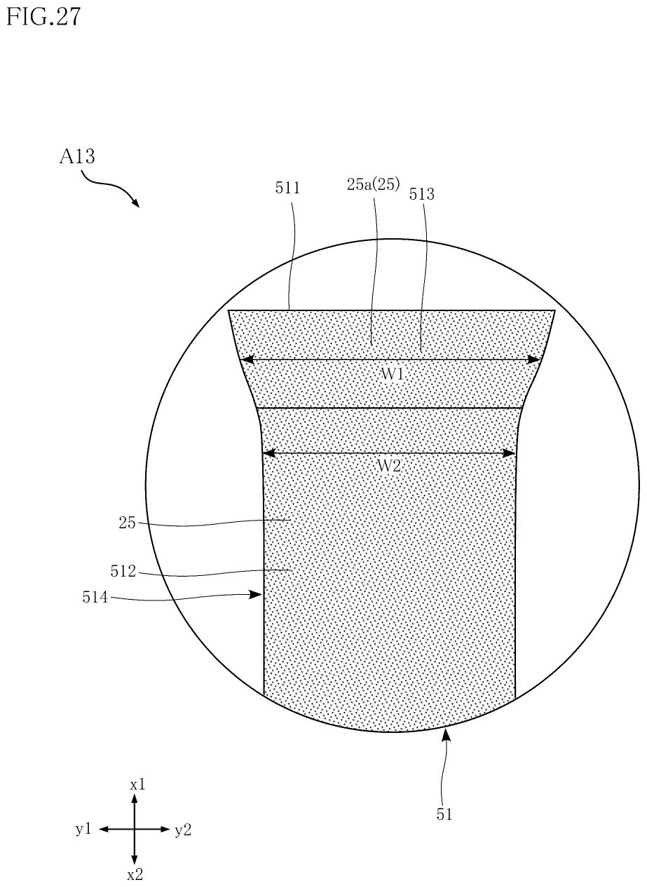

FIGS. 26 and 27 are views for illustrating a semiconductor device A13 according to a third variation of the first embodiment. FIG. 26 is a partial enlarged left-side view of the semiconductor device A13 and corresponds to FIG. 8. FIG. 27 is a partial enlarged bottom view of a first terminal 51 as seen in the z direction from the z2 side. In FIGS. 26 and 27, the plating layer 25 is represented with dots. The recesses of the semiconductor device A13 are formed by stamping, rather than by half-etching. That is, the recesses 513 of this variation are formed by displacing the material to the surrounding regions. As a result, each first terminal 51 has different dimensions at the recess 513 and at the full-thickness portion 514. That is, the width dimension (the y-direction dimension) W1 at the recess 513 is greater than the width dimension (the y-direction dimension) W2 at the full-thickness portion 514 where the bottom surface 512 is present.

In the first embodiment, each recess 513 is rectangular as viewed in z direction, but this is a non-limiting example. Each recess 513 may have different shapes, such as a semicircle.

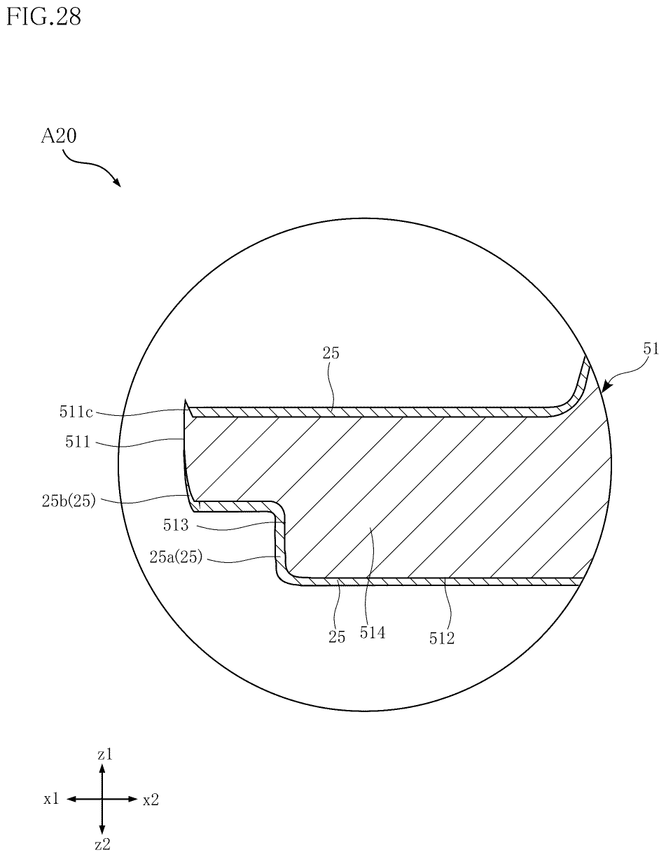

FIGS. 28 to 33 show other embodiments of the present disclosure. In these figures, components that are identical or similar to those of the above-described embodiment are given the same reference numerals as those in the above-described embodiment.

### Second Embodiment

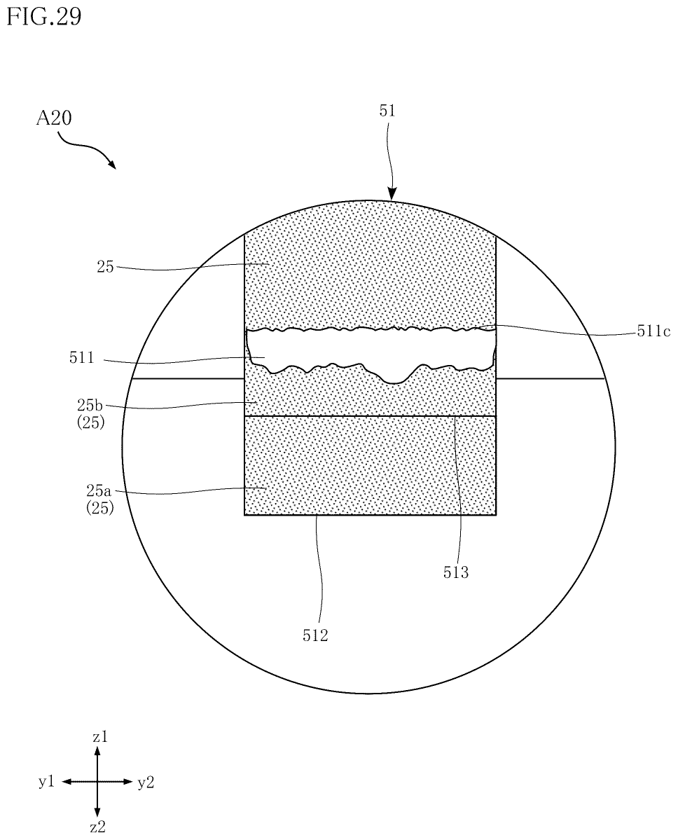

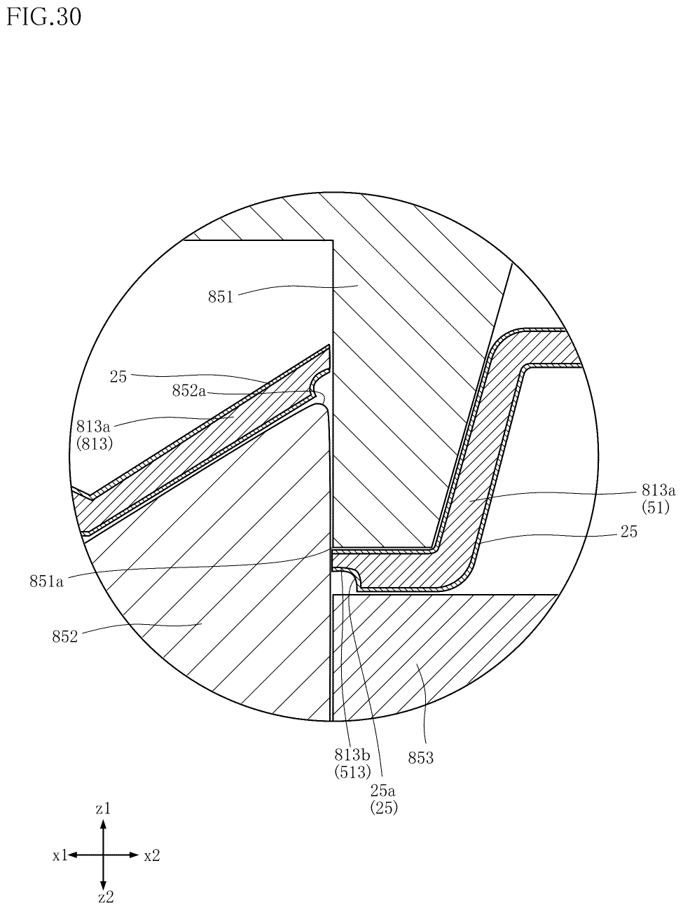

FIGS. 28 to 30 are views for illustrating a semiconductor device A20 according to a second embodiment of the present disclosure. FIG. 28 is a partial enlarged sectional view of the semiconductor device A20 and corresponds to FIG. 7. FIG. 29 is a partial enlarged sectional view of the semiconductor device A20 and corresponds to FIG. 8. FIG. 30 is a partial enlarged sectional view for illustrating a process of a method for manufacturing a semiconductor device A20 and corresponds to FIG. 20. The semiconductor device A20 of the present embodiment differs from the first embodiment in that a portion of the plating layer 25 is also present on a portion of the end surface 511. Other than that, the present embodiment is similar to the first embodiment regarding configuration and operations. Note that the present embodiment may be combined with any features of the first embodiment and its variations in any manner.

In the present embodiment, the plating layer 25 includes an end plating section 25b. The end plating section 25b is present on a portion of the end surface 511. In FIG. 29, the plating layer 25 including the end plating section 25b is represented with dots. As shown in FIG. 30, the cutting punch 852 of the cutting tool 85 used in the cutting step is provided with an edge section 852a for cutting a terminal portion 813a. In the present embodiment, the edge section 852a has a curved surface. The radius of curvature of the edge section 852a is larger than the radius of curvature of the edge section 851a of the cutting die 851 for cutting a terminal portion 813a. Consequently, at the time of cutting the terminal portion 813a, a portion of the plating layer 25 (the recess plating section 25a) present on the recess 813b of the terminal portion 813a is pulled and elongated. The elongated portion forms an end plating section 25b on a portion of the end surface 511, which is a cut surface of the terminal portion 813a. Likewise, an end plating section 25b is present on the end surface 521.

In the present embodiment, the cutting tool 85 employed in the cutting step uses an upper cut method, and thus cuts the terminal portions 813a and 814a from the z2 side in the z direction. Thus, the end plating section 25b is formed on a portion of the end surface 511 closer to the z2 side in the z direction. The end plating section 25b present on the end surface 511 is connected to the plating layer 25 applied to the recess 513 (the recess plating section 25a). Likewise, an end plating section 25b is present on the end surface 521 and is connected to the plating layer 25 applied to the recess 523 (the recess plating section 25a). As shown in FIG. 28, the end surface 511 has a burr 511c protruding in the z direction toward the z1 side and is inclined relative to the z direction at the portion connected to the recess 513.

In this embodiment, each first terminal 51 has a recess 513, and the recess 513 is coated with a recess plating section 25a. This ensures that the solder 95 adheres to the recess 513 and forms a solder fillet when the semiconductor device A20 is mounted. It is also ensured that the solder 95 adheres to the recess 523 of each second terminal 52 and forms a solder fillet. Consequently, the semiconductor device A20 can prevent defective soldering when it is mounted on a wiring board 9. In the present embodiment, in addition, each end surface 511 (end surface 521) has an end plating section 25b that is connected to the recess plating section 25a applied to the recess 513 (the recess 523). Thus, the solder 95 also adheres to the portion of the end surface 511 (the end surface 521), ensuring a solder fillet to form more appropriately. The semiconductor device A20 has a configuration in common with the semiconductor device A10, thereby achieving the same effect as the semiconductor device A10.

### Third Embodiment

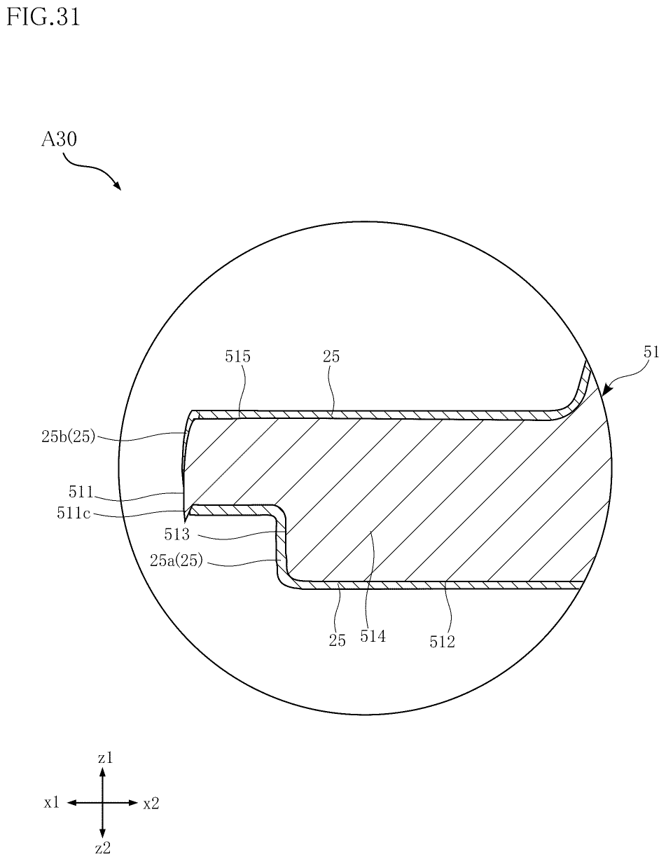

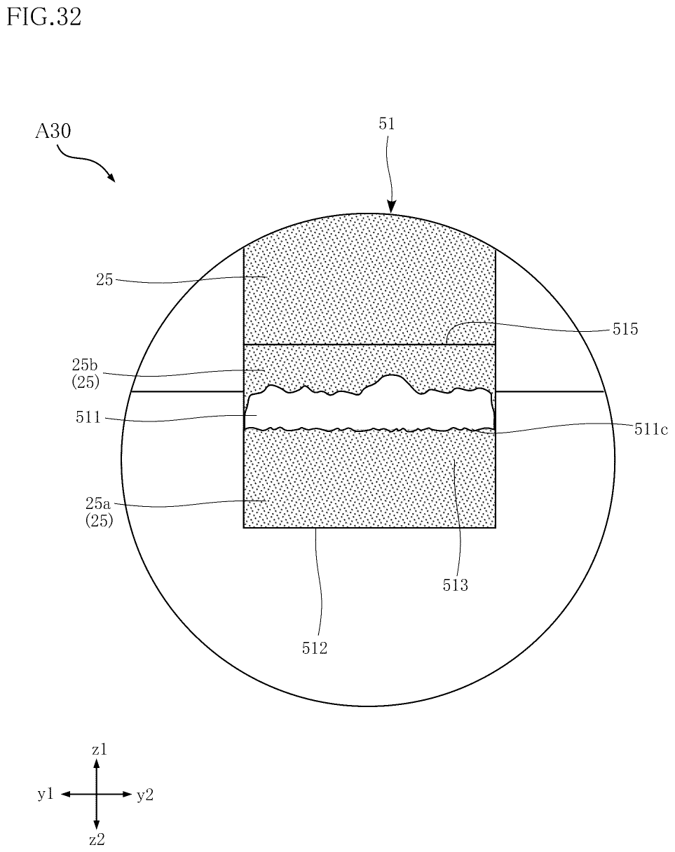

FIGS. 31 and 32 are views for illustrating a semiconductor device A30 according to a third embodiment of the present disclosure. FIG. 31 is a partial enlarged sectional view of the semiconductor device A30 and corresponds to FIG. 7. FIG. 32 is a partial enlarged sectional view of the semiconductor device A30 and corresponds to FIG. 8. The semiconductor device A30 of the present embodiment differs from the second embodiment in that a portion of the plating layer 25 is present on a portion of the end surface 511 that is closer to the z1 side in the z direction. Other than that, the present embodiment is similar to the second embodiment regrading configuration and operations. Note that the present embodiment may be combined with any features of the first and second embodiments and their variations in any manner.

In the present embodiment, an end plating section 25b is present on the portion of the end surface 511 closer to the z1 side in the z direction. In FIG. 32, the plating layer 25 including the end plating section 25b is represented with dots. In the present embodiment, the cutting tool 85 employed in the cutting step uses a down-cut method, so that the cutting punch 852 cuts the terminal portions 813a and 814a from the z1 side in the z direction. Consequently, at the time of cutting the terminal portion 813a, a portion of the plating layer 25 on the upper surface 515 of the terminal portion 813a, which faces the z1 side in the z direction, is pulled and elongated. The elongated portion forms an end plating section 25b on a portion of the end surface 511, which is a cut surface of the terminal portion 813a. Thus, the end plating section 25b is formed on a portion of the end surface 511 closer to the z1 side in the z direction. In contrast, a portion of the end surface 511 closer to the z2 side in the z direction is exposed from the end plating section 25b. The ratio of the regions of the end surface 511, one covered with the end plating section 25b and one exposed from the end plating section 25b, can be adjusted by changing the radius of curvature of the edge section 852a of the cutting punch 852 or the clearance between the cutting die 851 and the cutting punch 852. Likewise, an end plating section 25b is present on a portion of the end surface 521. As shown in FIG. 31, the end surface 511 has a burr 511c protruding in the z direction toward the z2 side and is inclined relative to the z direction at a portion connected to the upper surface 515.

In this embodiment, each first terminal 51 has a recess 513, and the recess 513 is coated with a recess plating section 25a. This ensures that the solder 95 adheres to the recess 513 and forms a solder fillet when the semiconductor device A30 is mounted. It is also ensured that the solder 95 adheres to the recess 523 of each second terminal 52 and forms a solder fillet. Consequently, the semiconductor device A30 can prevent defective soldering when the semiconductor device A30 is mounted on a wiring board 9. In the present embodiment, in addition, the end surface 511 (the end surface 521) has a region coated with the end plating section 25b and a region exposed from the end plating section 25b. The coated region is located on the z1 side in the z direction, and the exposed region is on the z2 side in the z direction. The solder 95 does not easily adhere to the exposed region of the end surface 511 (the end surface 521). Thus, increasing the region of the end surface 511 (the end surface 521) exposed from the end plating section 25b is effective for preventing solder from flowing beyond the recess 513 (the recess 523) to form a solder fillet on the end surface 511 (the end surface 521). The semiconductor device A30 has a configuration in common with the semiconductor device A10, thereby achieving the same effect as the semiconductor device A10.

### Fourth Embodiment

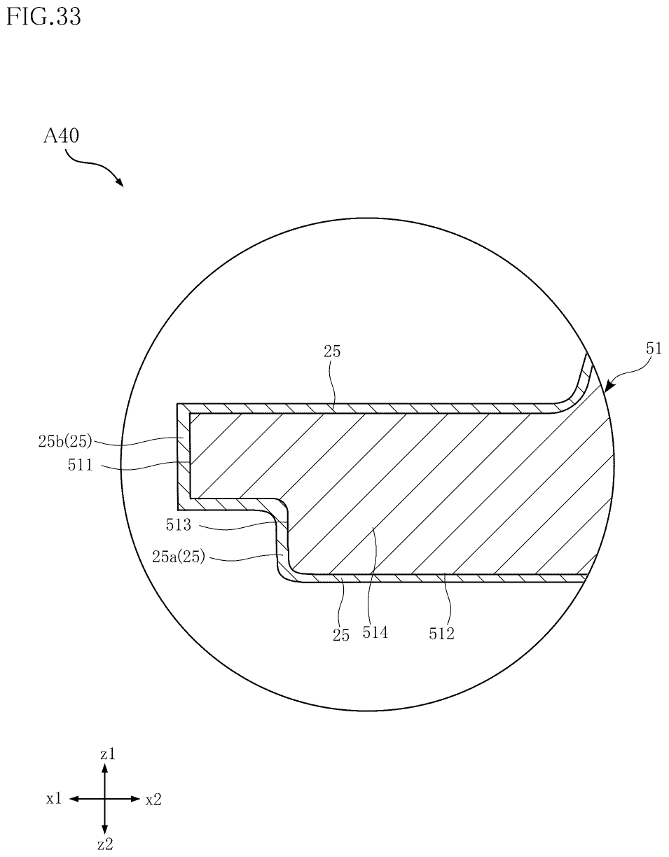

FIG. 33 is a view for illustrating a semiconductor device A40 according to a fourth embodiment of the present disclosure. FIG. 33 is a partial enlarged sectional view of the semiconductor device A40 and corresponds to FIG. 7. The semiconductor device A40 of the present embodiment differs from the first embodiment in that a plating layer 25 is present on the entire region of the end surface 511. Other than that, the present embodiment is similar to the first embodiment regarding configuration and operations. Note that the present embodiment may be combined with any features of the first to third embodiments and their variations in any manner.

In the present embodiment, the entire regions of the end surfaces 511 and 521 are coated with the end plating section 25b. The method for manufacturing the semiconductor device A40 according to the fourth embodiment differs from that of the first embodiment. In the manufacturing method of the fourth embodiment, the terminal portions 813a and 814a are bent and cut after the sealing resin 7 is formed and before the plating layer 25 is formed. After the terminal portions 813a and 814a are cut, the plating layer 25 is formed to coat the portions of the first terminals 51 and the second terminals 52 exposed from the sealing resin 7. The portions of the plating layer 25 formed on the end surfaces 511 and 521 are the end plating sections 25b. Also, the portions of the plating layer 25 coating the recesses 513 and 523 are the recess plating sections 25a.

In this embodiment, each first terminal 51 has a recess 513, and the recess 513 is coated with a recess plating section 25a. This ensures that the solder 95 adheres to the recess 513 and forms a solder fillet when the semiconductor device A40 is mounted. It is also ensured that the solder 95 adheres to the recess 523 of each second terminal 52 and forms a solder fillet. Consequently, the semiconductor device A40 can prevent defective soldering when the semiconductor device A40 is mounted on a wiring board 9. In the present embodiment, in addition, an end plating section 25b is present on the entire region of the end surface 511 (the end surface 521). This ensures that the solder 95 adheres to the entire region of the end surface 511 (the end surface 521) and forms a solder fillet that also covers the end surface 511 (the end surface 521). The semiconductor device A40 has a configuration in common with the semiconductor device A10, thereby achieving the same effect as the semiconductor device A10.

The semiconductor device and the method for manufacturing the semiconductor device according to the present disclosure are not limited to those of the embodiments described above. Various modifications in design may be made freely in the specific configuration of each part of the semiconductor device according to the present disclosure, as well as to the specific processing of each step of the manufacturing method according to the present disclosure. The present disclosure includes embodiments described in the following clauses.

### Clause 1.

A semiconductor device comprising:
a semiconductor element (11);
a sealing resin (7) covering the semiconductor element;
a terminal (51) electrically connected to the semiconductor element and protruding from the sealing resin in a first direction (x direction) orthogonal to a thickness direction (z direction); and
a plating layer (25) located on the terminal,
wherein the terminal includes an end surface (511) located at a distal end protruding from the sealing resin, a first surface (512) facing a first side in the thickness direction (z2 side in z direction), and a recess (513) recessed from both the end surface and the first surface, and
the plating layer includes a recess plating section (25a) located on at least a portion of the recess.

### Clause 2. (FIG. 7)

The semiconductor device according to Clause 1, wherein the recess has a first dimension (T1) in the thickness direction, the first dimension being at least ¼ and at most ¾ of a second dimension (T2) in the thickness direction of a full-thickness portion (514) of the terminal where the first surface is present.

### Clause 3.

The semiconductor device according to Clause 1 or 2, wherein the plating layer includes an end plating section (25b) located on at least a portion of the end surface.

Clause 4. (fourth embodiment, FIG. 33)

The semiconductor device according to Clause 3, wherein the end plating section is located on an entire region of the end surface.

Clause 5. (second embodiment, FIGS. 28 and 29)

The semiconductor device according to Clause 3, wherein the end plating section is located on a portion of the end surface closer to the first side.

Clause 6. (third embodiment, FIGS. 31 and 32)

The semiconductor device according to Clause 3, wherein the end plating section is located on a portion of the end surface closer to a second side (z1 side in z direction) opposite the first side.

### Clause 7.

The semiconductor device according to any one of Clauses 1 to 6, wherein the recess extends across an entirety of the terminal in a second direction (y direction) orthogonal to the thickness direction and the first direction.

Clause 8. (first and second variations of first embodiment, FIGS. 22 to 25)

The semiconductor device according to any one of Clauses 1 to 6, wherein the first surface is connected to the end surface.

Clause 9. (third variation of first embodiment, FIG. 27)

The semiconductor device according to any one of Clauses 1 to 8, wherein in a second direction orthogonal to the thickness direction and the first direction, the terminal has a greater dimension at a portion where the recess is present than at a portion where the first surface is present.

### Clause 10. (FIG. 9)

The semiconductor device according to any one of Clauses 1 to 9, wherein the terminal further includes a first bend (516) that bends toward the first side in the thickness direction,
a minimum radius of curvature (R1) on an inside surface of the first bend is greater than a second dimension (T2) of a full-thickness portion of the terminal where the first surface is present.

### Clause 11. (FIG. 9)

The semiconductor device according to Clause 10, wherein the terminal further includes a second bend (517) located between the first bend and the end surface, and
a minimum radius of curvature (R2) on an inside surface of the second bend is greater than the second dimension.

### Clause 12.

The semiconductor device according to any one of Clauses 1 to 11, wherein the plating layer contains Sn.

### Clause 13.

A method for manufacturing a semiconductor device, the method comprising:
preparing a lead frame that includes a terminal portion, the terminal portion including a first surface facing a first side in a thickness direction and a recess recessed from the first surface in the thickness direction;
applying a plating layer to the terminal portion; and
cutting the terminal portion with a cutting tool along a cutting line that intersects the recess.

### Clause 14.

The method according to Clause 13, wherein the cutting tool includes a cutting die and a cutting punch, and
the terminal portion is cut from the first side with the cutting punch.

### Clause 15.

The method according to Clause 13, wherein the cutting tool includes a cutting die and a cutting punch, and
the terminal portion is cut from a second side opposite the first side in the thickness direction, with the cutting punch.

### Clause 16.

The method according to Clause 14 or 15, wherein the cutting punch includes a first edge for cutting the terminal portion, and
the first edge includes a curved surface.

### Clause 17. (FIG. 17)

The method according to any one of Clauses 13 to 16, further comprising bending the terminal portion with a forming tool (86) before the cutting,
wherein the forming tool includes a forming die (861) and a forming punch (862), and
the forming die includes a shoulder (861a) having a minimum radius of curvature (R3) equal to or greater than a dimension (T2) of the lead frame in the thickness direction.

### Clause 18. (FIG. 17)

The method according to Clause 17, wherein the forming punch includes a shoulder (862a) having a minimum radius of curvature (R4) equal to or greater than the dimension of the lead frame in the thickness direction.

### REFERENCE NUMERALS

A10, A11, A12, A13, A20, A30, A40: semiconductor device
11: first semiconductor element
111: element obverse surface
112: element reverse surface 11A: electrode
12: second semiconductor element
121: element obverse surface
122: element reverse surface 12A: electrode
13: insulating element 131: element obverse surface
132: element reverse surface 13A: first electrode
13B: second electrode 19: conductive bonding material
25: plating layer 25a: recess plating section
25b: end plating section 2: conductive member
3: first die pad 31: obverse surface
32: reverse surface 4: second die pad
41: obverse surface 42: reverse surface
51, 51a, 51b: first terminal 511: end surface
511c: burr 512: bottom surface
513: recess 514: full-thickness portion
515: upper surface 516: first bend
517: second bend 53: pad
54: connecting portion 52, 52a, 52b: second terminal
521: end surface 521c: burr
522: bottom surface 523: recess
524: full-thickness portion 525: upper surface
526: first bend 527: second bend
55: pad 56: connecting portion
61 to 64: wire 7: sealing resin
71: resin top surface 72: resin bottom surface
73 to 76: resin side surface 731: resin first region
732: resin second region 733: resin third region
741: resin fourth region 742: resin fifth region
743: resin sixth region 751: resin seventh region
752: resin eighth region 753: resin ninth region
761: resin tenth region 762: resin eleventh region
763: resin twelfth region 81: lead frame
81A: obverse surface 81B: reverse surface
811: outer frame 812A: first die pad
812B: second die pad 813: first lead
813a: terminal portion 813b: recess
813c: first bend 813d: second bend
814: second lead 814a: terminal portion
814b: recess 814c: first bend
814d: second bend 815: connecting portion
816: dam bar 85: cutting tool
851: cutting die 851a: edge section
852: cutting punch 852a: edge section
853: stripper block 86: forming tool
861: die block 861a: shoulder
862: punch 862a: shoulder
863: stripper block 9: wiring board
95: solder

1. A semiconductor device comprising:
a semiconductor element;
a sealing resin covering the semiconductor element;
a terminal electrically connected to the semiconductor element and protruding from the sealing resin in a first direction orthogonal to a thickness direction; and
a plating layer located on the terminal,
wherein the terminal includes an end surface located at a distal end protruding from the sealing resin, a first surface facing a first side in the thickness direction, and a recess recessed from both the end surface and the first surface, and
the plating layer includes a recess plating section located on at least a portion of the recess.

2. The semiconductor device according to claim 1, wherein the recess has a first dimension in the thickness direction, the first dimension being at least ¼ and at most ¾ of a second dimension in the thickness direction of a full-thickness portion of the terminal where the first surface is present.

3. The semiconductor device according to claim 1, wherein the plating layer includes an end plating section located on at least a portion of the end surface.

4. The semiconductor device according to claim 3, wherein the end plating section is located on an entire region of the end surface.

5. The semiconductor device according to claim 3, wherein the end plating section is located on a portion of the end surface closer to the first side.

6. The semiconductor device according to claim 3, wherein the end plating section is located on a portion of the end surface closer to a second side opposite the first side.

7. The semiconductor device according to claim 1, wherein the recess extends across an entirety of the terminal in a second direction orthogonal to the thickness direction and the first direction.

8. The semiconductor device according to claim 1, wherein the first surface is connected to the end surface.

9. The semiconductor device according to claim 1, wherein in a second direction orthogonal to the thickness direction and the first direction, the terminal has a greater dimension at a portion where the recess is present than at a portion where the first surface is present.

10. The semiconductor device according to claim 1, wherein the terminal further includes a first bend that bends toward the first side in the thickness direction,
a minimum radius of curvature on an inside surface of the first bend is greater than a second dimension of a full-thickness portion of the terminal where the first surface is present.

11. The semiconductor device according to claim 10, wherein the terminal further includes a second bend located between the first bend and the end surface, and
a minimum radius of curvature on an inside surface of the second bend is greater than the second dimension.

12. The semiconductor device according to claim 1, wherein the plating layer contains Sn.

13. A method for manufacturing a semiconductor device, the method comprising:
preparing a lead frame that includes a terminal portion, the terminal portion including a first surface facing a first side in a thickness direction and a recess recessed from the first surface in the thickness direction;
applying a plating layer to the terminal portion; and
cutting the terminal portion with a cutting tool along a cutting line that intersects the recess.

14. The method according to claim 13, wherein the cutting tool includes a cutting die and a cutting punch, and
the terminal portion is cut from the first side with the cutting punch.

15. The method according to claim 13, wherein the cutting tool includes a cutting die and a cutting punch, and
the terminal portion is cut from a second side opposite the first side in the thickness direction, with the cutting punch.

16. The method according to claim 14, wherein the cutting punch includes a first edge for cutting the terminal portion, and
the first edge includes a curved surface.

17. The method according to claim 13, further comprising bending the terminal portion with a forming tool before the cutting,
wherein the forming tool includes a forming die and a forming punch, and
the forming die includes a shoulder having a minimum radius of curvature equal to or greater than a dimension of the lead frame in the thickness direction.

18. The method according to claim 17, wherein the forming punch includes a shoulder having a minimum radius of curvature equal to or greater than the dimension of the lead frame in the thickness direction.
